(19) United States
(12) Patent Application Publication
(10) Pub. No.: US 2024/0213315 A1
(43) Pub. Date: Jun. 27, 2024

(54) GATE-ALL-AROUND TRANSISTORS WITH CLADDED SOURCE/DRAIN REGIONS

(71) Applicant: International Business Machines Corporation, Armonk, NY (US)

(72) Inventors: Julien Frougier, Albany, NY (US); Ruilong Xie, Niskayuna, NY (US); Andrew M. Greene, Slingerlands, NY (US); Curtis S. Durfee, Schenectady, NY (US); Oleg Gluschenkov, Tannersville, NY (US); Andrew Gaul, Halfmoon, NY (US)

(21) Appl. No.: 18/087,990

(22) Filed: Dec. 23, 2022

(51) Int. Cl. H01L 29/06; H01L 29/08; H01L 29/10; H01L 29/423

(52) U.S. Cl. CPC H01L 29/0665; H01L 29/0847; H01L 29/1037; H01L 29/1095; H01L 29/42392

(57) ABSTRACT

A semiconductor structure includes a gate region, a source/drain region, and a nanosheet semiconductor layer extending continuously across the gate region and the source/drain region. The nanosheet semiconductor layer includes a first portion in the gate region and a second portion in the source/drain region. The source/drain region includes a cladded epitaxial layer wrapping around the second portion of the nanosheet semiconductor layer.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost.

### SUMMARY

Embodiments of the invention provide techniques for forming gate-all-around transistors with cladded source/drain regions.

In one embodiment, a semiconductor structure includes a gate region, a source/drain region, and a nanosheet semiconductor layer extending continuously across the gate region and the source/drain region. The nanosheet semiconductor layer includes a first portion extending through the gate region and a second portion extending through the source/drain region. The source/drain region includes a cladded epitaxial layer wrapping around the second portion of the nanosheet semiconductor layer.

In another embodiment, a gate-all-around transistor includes a gate region, a source/drain region, and a plurality of nanosheet semiconductor layers extending continuously across the gate region and the source/drain region. Each of the plurality of nanosheet semiconductor layers includes a first portion extending through the gate region and a second portion extending through the source/drain region. The source/drain region includes cladded epitaxial layers wrapping around the second portion of each of the plurality of nanosheet semiconductor layers.

In another embodiment, an integrated circuit includes a gate-all-around transistor structure including a gate region, a source/drain region, and a plurality of nanosheet semiconductor layers extending continuously across the gate region and the source/drain region, each of the plurality of nanosheet semiconductor layers including a first portion extending through the gate region and a second portion extending through the source/drain region. The source/drain region includes cladded epitaxial layers wrapping around the second portion of each of the plurality of nanosheet semiconductor layers.

These and other features and advantages of embodiments described herein will become more apparent from the accompanying drawings and the following detailed description.

### BRIEF DESCRIPTION OF THE DRAWINGS

FIGS. 1A and 1B show views of a gate-all-around transistor structure with self-aligned junctions, cladded source/drain epitaxial layers and wrap-all-around contacts, according to an embodiment of the invention.

FIGS. 2A and 2B show views of another gate-all-around transistor structure with self-aligned junctions, cladded source/drain epitaxial layers and wrap-all-around contacts, according to an embodiment of the invention.

FIGS. 3A and 3B shows views of a gate-all-around transistor structure without self-aligned junctions, cladded source/drain epitaxial layers and wrap-all-around contacts, according to an embodiment of the invention.

FIG. 4 shows a top-down view of a structure including fin regions, gate regions, and spacers, according to an embodiment of the invention.

FIGS. 5A-5D show views of a structure with a substrate, according to an embodiment of the invention.

FIGS. 6A-6D show views of the structure of FIGS. 5A-5D following formation of a punch through stopper layer, according to an embodiment of the invention.

FIGS. 7A-7D show views of the structure of FIGS. 6A-6D following formation of a nanosheet stack, according to an embodiment of the invention.

FIGS. 8A-8D show views of the structure of FIGS. 7A-7D following fin formation, according to an embodiment of the invention.

FIGS. 9A-9D show views of the structure of FIGS. 8A-8D following formation of shallow trench isolation regions, according to an embodiment of the invention.

FIGS. 10A-10D show views of the structure of FIGS. 9A-9D following formation of a dummy oxide layer, dummy gate layers, and a sacrificial spacer layer, according to an embodiment of the invention.

FIGS. 11A-11D show views of the structure of FIGS. 10A-10D following formation of an interlayer dielectric layer, according to an embodiment of the invention.

FIGS. 12A-12D show views of the structure of FIGS. 11A-11D following removal of the sacrificial spacer and sacrificial layers of the nanosheet stack, according to an embodiment of the invention.

FIGS. 13A-13D show views of the structure of FIGS. 12A-12D following self-aligned junction implantation, according to an embodiment of the invention.

FIGS. 14A-14D show views of the structure of FIGS. 13A-13D following selective growth of epitaxial layers on doped semiconductor regions, according to an embodiment of the invention.

FIGS. 15A-15D show views of the structure of FIGS. 14A-14D following formation of spacers, according to an embodiment of the invention.

FIGS. 16A-16D show views of the structure of FIGS. 15A-15D following removal of the interlayer dielectric layer and etch-back of portions of the spacers, according to an embodiment of the invention.

FIGS. 17A-17D show views of the structure of FIGS. 16A-16D following thinning of portions of the nanosheet semiconductor layers of the nanosheet stack, according to an embodiment of the invention.

FIGS. 18A-18D show views of the structure of FIGS. 17A-17D following formation of cladded source/drain epitaxy regions surrounding exposed portions of the nanosheet semiconductor layers of the nanosheet stack, according to an embodiment of the invention.

FIGS. 19A-19D show views of the structure of FIGS. 18A-18D following formation of an interlayer dielectric layer, according to an embodiment of the invention.

FIGS. 20A-20D show views of the structure of FIGS. 19A-19D following removal of the dummy gate layers, the dummy oxide layer, and etch-back of the spacers, according to an embodiment of the invention.

FIGS. 21A-21D show views of the structure of FIGS. 20A-20D following formation of gate layers and self-aligned contact capping layers, according to an embodiment of the invention.

FIGS. 22A-22D show views of the structure of FIGS. 21A-21D following formation of wrap-all-around contacts, according to an embodiment of the invention.

FIGS. 23A-23D show views of the structure of FIGS. 11A-11D following removal of the sacrificial spacer, according to an embodiment of the invention.

FIGS. 24A-24D show views of the structure of FIGS. 23A-23D following self-aligned junction implantation, according to an embodiment of the invention.

FIGS. 25A-25D show views of the structure of FIGS. 24A-24D following selective removal of doped portions of the sacrificial layers of the nanosheet stack, according to an embodiment of the invention.

FIGS. 26A-26D show views of the structure of FIGS. 25A-25D following formation of spacers, according to an embodiment of the invention.

FIGS. 27A-27D show views of the structure of FIGS. 26A-26D following removal of the interlayer dielectric layer and removal of exposed portions of the sacrificial layers of the nanosheet stack, according to an embodiment of the invention.

FIGS. 28A-28D show views of the structure of FIGS. 27A-27D following thinning of portions of the nanosheet semiconductor layers of the nanosheet stack, according to an embodiment of the invention.

FIGS. 29A-29D show views of the structure of FIGS. 28A-28D following formation of cladded source/drain epitaxy regions surrounding exposed portions of the nanosheet semiconductor layers of the nanosheet stack, according to an embodiment of the invention.

FIGS. 30A-30D show views of the structure of FIGS. 29A-29D following formation of an interlayer dielectric layer and removal of the dummy gate layers, the dummy oxide layer, and remaining portions of the sacrificial layers of the nanosheet stack, according to an embodiment of the invention.

FIGS. 31A-31D show views of the structure of FIGS. 30A-30D following formation of gate layers and self-aligned contact capping layers, according to an embodiment of the invention.

FIGS. 32A-32D show views of the structure of FIGS. 31A-31D following formation of wrap-all-around contacts, according to an embodiment of the invention.

FIG. 33 depicts an integrated circuit including one or more nanosheet transistor structures with self-aligned junctions, cladded source/drain epitaxial layers and wrap-all-around contacts, according to an embodiment of the invention.

### DETAILED DESCRIPTION

Illustrative embodiments of the invention may be described herein in the context of illustrative methods for forming nanosheet transistor structures with self-aligned junctions, cladded source/drain epitaxial layers and wrap-all-around contacts, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves removing sacrificial layers, which may be formed of silicon germanium (SiGe), between sheets of channel material, which may be formed of silicon (Si).

Horizontal gate-all-around technology, such as using nanosheet channels, has been identified as an architecture for continuing logic scaling beyond 5 nm node size. Despite progress in integration processing, there are fundamental engineering challenges which need to be solved to reach full performance and manufacturing potential. These challenges include, but are not limited to, junction design and alignment to gate regions, reliable and repeatable formation of source/drain epitaxy regions, formation of wrap-all-around contacts with a maximized contact area, and reduction of parasitic capacitance through enablement of low-k inner spacers. Illustrative embodiments provide approaches which meet these and other challenges.

In horizontal gate-all-around technology, epitaxial nucleation from the edge of channel layers of the nanosheet stack is very challenging. From an integration perspective, the epitaxial nucleation requires very aggressive pre-cleans which can created downstream processing issues such as, but not limited to, epitaxy nodules at the top of the gates. Even with a carefully designed pre-cleaned sequence, there may be missing epitaxial issues which is a fundamental yield detractor for horizontal gate-all-around technology.

A process flow for forming horizontal gate-all-around devices with self-aligned junctions and cladded source/drain epitaxy regions with enhanced wrap-all-around contacts will now be described. The process flow includes formation a nanosheet epitaxy stack (e.g., of alternating semiconductor and sacrificial nanosheet layers), followed by formation of fins and shallow trench isolation (STI) regions. Dummy gates and sacrificial gate spacers are then formed, followed by deposition of an interlayer dielectric (ILD) and planarization. The sacrificial gate spacers are then removed, followed be removal of the sacrificial layers of the nanosheet stack (e.g., silicon germanium (SiGe) suspensions). Self-aligned junctions are then formed in portions of the nanosheet semiconductor layers of the nanosheet stack by implantation through the open cavities formed by removal of the sacrificial gate spacers. The implanted self-aligned junctions are then subject to a selective epitaxial growth process. Final spacer and inner spacer material is then formed, followed by selective removal of the ILD and spacer material in areas where source/drain regions will be formed. As an optional step, the stacked nanosheet layers may be thinned in the areas where the source/drain regions will be formed. A cladded source/drain epitaxy is then grown around the uncut nanosheet semiconductor layers in the nanosheet stack in the source/drain region areas. An ILD is then deposited and planarized, followed by removal of the dummy gates and spacer material in the gate regions. A gate stack (e.g., a high-k metal gate (HKMG)) and self-aligned contact (SAC) capping layers are then formed. Wrap-all-around contacts are then formed.

Such processing may be utilized to form semiconductor devices which are gate-all-around devices exhibiting continuous nanosheet layers between gate and source/drain regions. The devices further have source/drain epitaxial layers which wrap around the nanosheet layers in the source/drain regions. The devices may also have gate spacers and inner spacers which are formed of the same material, as well as wrap-all-around contacts of the uncut nanosheet layers in the source/drain regions. Such devices provide self-alignment of junctions to the gates, which provides significant advantages relative to lateral drive-in anneal processing. Further, there is drastic improvement of the surface area (e.g., of the nanosheet layers) which is available for source/drain epitaxial nucleation. There is further drastic improvement of the contact area, provided by the wrap-all-around contacts of the uncut sheets (e.g., the nanosheet semiconductor layers of the nanosheet stack) in the source/drain regions. Parasitic capacitance reduction is also achieved through the use of a low-K inner spacer formed with the same low-K material used for the gate spacers (e.g., rather than using a relatively higher-K spacer material such as silicon nitride (SiN)).

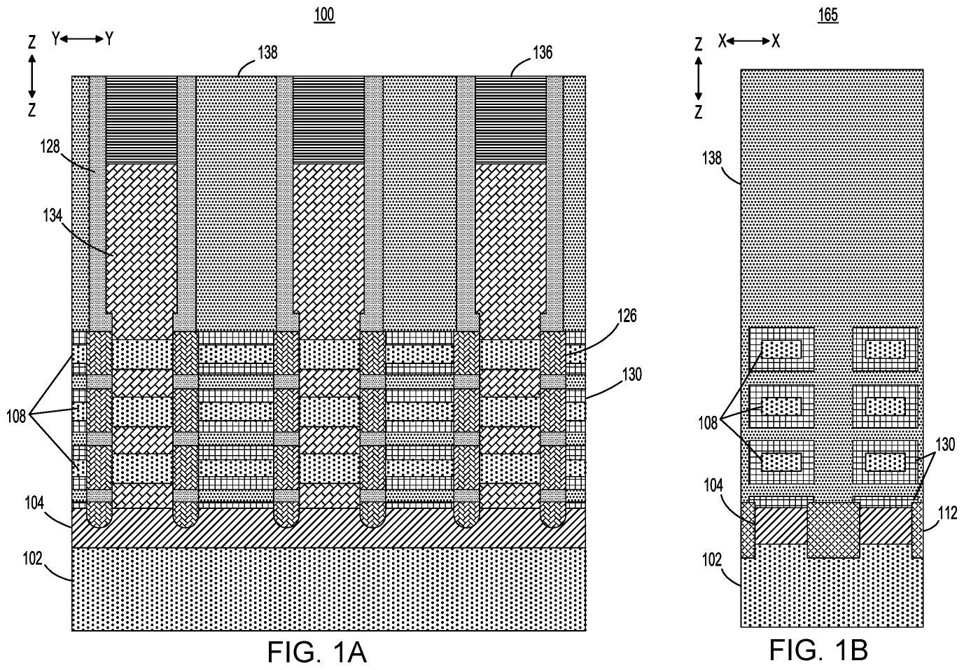

FIGS. 1A and 1B show respective side cross-sectional views 100 and 165 of a structure formed using the processing described above, which includes a substrate 102, a punch through stopper (PTS) layer 104, nanosheet semiconductor layers 108, STI regions 112, self-aligned doped junctions 126, spacers 128 (e.g., providing both gate spacers and inner spacers), cladded source/drain epitaxial layers 130 which surround portions of the nanosheet semiconductor layers 108 in the source/drain region areas, gates 134, SAC capping layers 136, and wrap-all-around contacts 138. The nanosheet semiconductor layers 108 have first portions in the gate regions of the structure which act as channels for gate-all-around transistor devices. The nanosheet semiconductor layers 108 also have second portions in the extension regions of the structure (e.g., where the source/drain regions are formed, and in the gate spacer/inner spacer region).

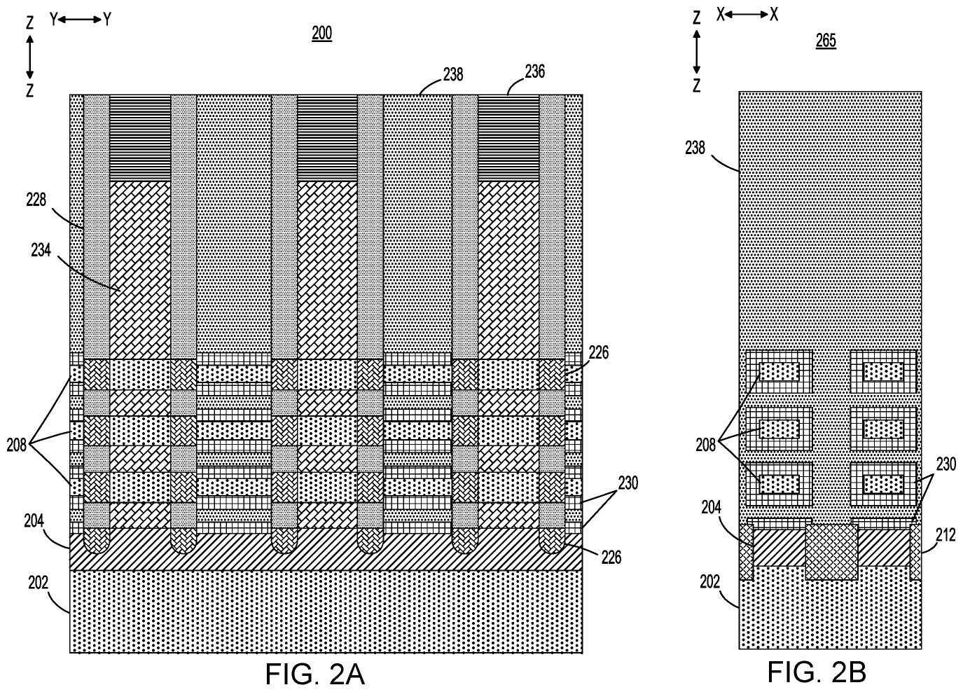

FIGS. 2A and 2B show respective side cross-sectional views 200 and 265 of a structure formed using processing similar to that described above, which includes a substrate 202, a PTS layer 204, nanosheet semiconductor layers 208, STI regions 212, self-aligned doped junctions 226, spacers 228 (e.g., providing both gate spacers and inner spacers), cladded source/drain epitaxial layers 230 which surround portions of the nanosheet layers 208 in the source/drain region areas, gates 234, SAC capping layers 236, and wrap-all-around contacts 238. The self-aligned doped junctions 226 of the structure of FIGS. 2A and 2B differ from the self-aligned doped junctions 126 of the structure of FIGS. 1A and 1B (e.g., the self-aligned doped junctions 126 are “taller” in direction Z than the self-aligned doped junctions 226). The nanosheet semiconductor layers 208, similar to the nanosheet semiconductor layers 108, have first portions in the gate regions of the structure which act as channels for gate-all-around transistor devices. The nanosheet semiconductor layers 208 also have second portions in the extension regions of the structure (e.g., where the source/drain regions are formed, and in the gate spacer/inner spacer region).

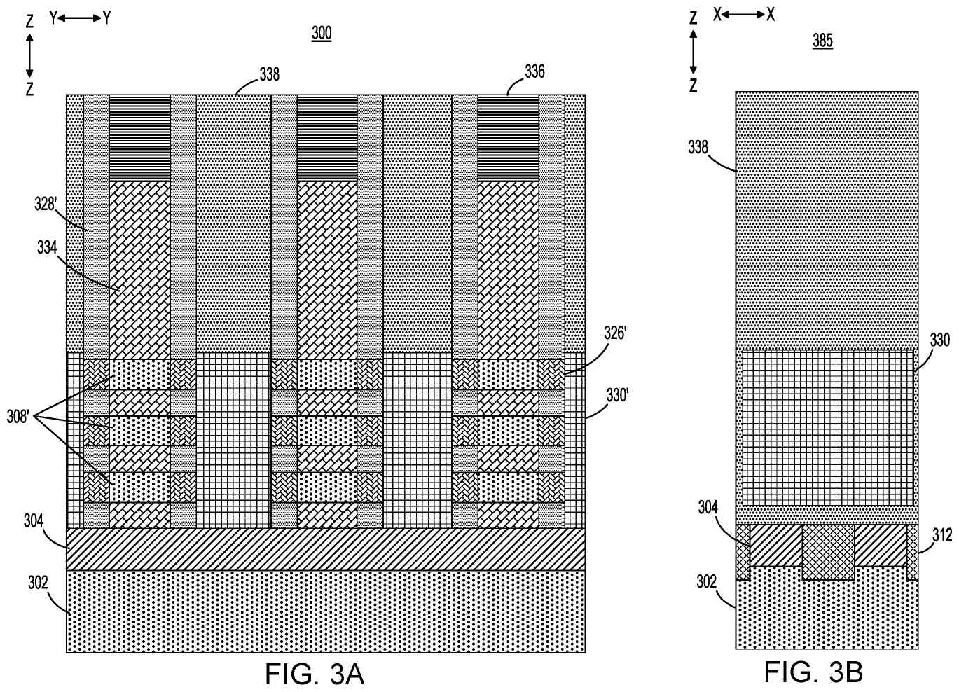

FIGS. 3A and 3B show respective side cross-sectional views 300 and 365 of a convention structure formed without the processing described above, which includes a substrate 302, PTS layer 304, nanosheet semiconductor layers 308, STI regions 312, self-aligned doped junctions 326, spacers 328 (e.g., providing both gate spacers and inner spacers), source/drain regions 330, gates 334, SAC capping layers 336 and contacts 338. Here, the nanosheet semiconductor layers 308 are not continuous through the areas where the source/drain regions 330 are formed. Further, the contacts 338 do not wrap around the source/drain regions 330.

Illustrative embodiments provide approaches for forming semiconductor devices including a gate-all-around FET with first and second source/drain regions. The first source/drain region includes a first plurality of silicon layers between top and bottom silicon germanium layers. The second source/drain region includes a second plurality of silicon layers between top and bottom silicon germanium layers. A plurality of continuous sheets extend between the first and second source/drain regions, with each of the continuous sheets being aligned with one of the silicon layers of the first plurality of silicon layers and one of the silicon layers of the second plurality of silicon layers. A metal gate region wraps around the plurality of continuous sheets. The device also includes a plurality of first gate spacers between the plurality of continuous sheets and the first source/drain region and a plurality of second gate spacers between the plurality of continuous sheets and the second source/drain region. A plurality of source/drain spacers are aligned with the continuous sheets of the plurality of continuous sheets, adjacent to the plurality of first gate spacers and the plurality of second gate spacers and between the top and bottom silicon germanium layers. The device may further include first and second wrap-all-around contacts surrounding the first and second source/drain regions.

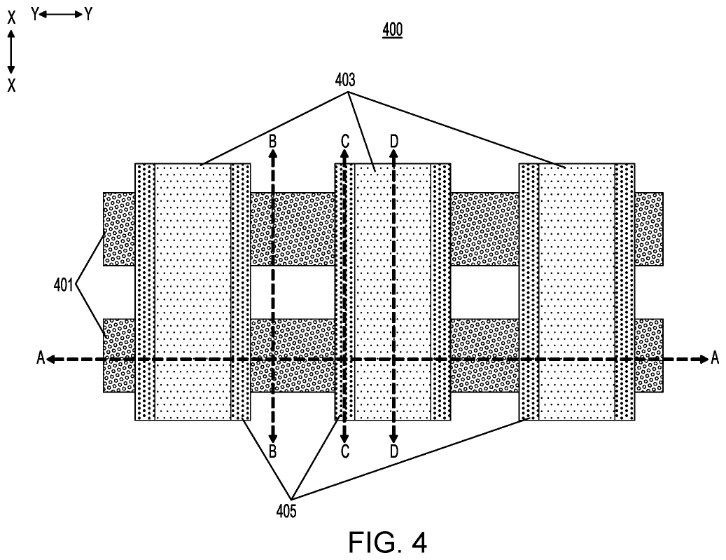

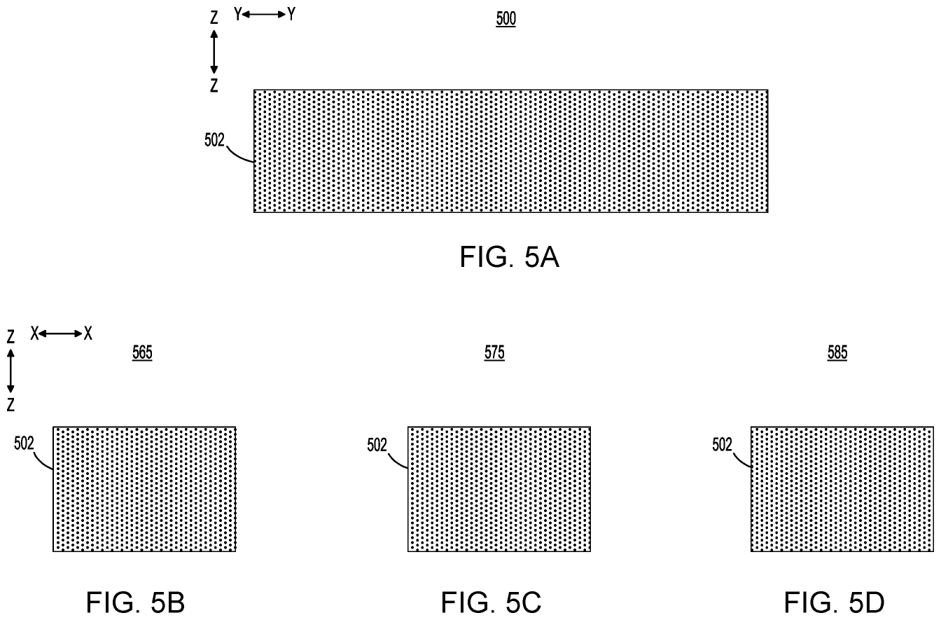

FIG. 4 shows a top-down view 400 of a structure including fin regions 401, gate regions 403, and spacers 405. The top-down view 400 also shows lines A-A, B-B, C-C and D-D illustrating where cross-sectional views of subsequent views are taken. Subsequent “A” figures (e.g., FIGS. 5A-32A) are taken along the line A-A in direction Y (e.g., across the gate regions 403). Subsequent “B” figures (e.g., FIGS. 5B-32B) are taken along the line B-B in direction X (e.g., in a source/drain region between two of the gate regions 403). Subsequent “C” figures (e.g., FIGS. 5C-32C) are taken along the line C-C in direction X (e.g., along one of the spacers 405). Subsequent “D” figures are taken along the line D-D in direction X (e.g., along one of the gate regions 403).

FIGS. 5A-5D show respective cross-sectional view 500, 565, 575 and 585 of a structure with a starting substrate 502. The substrate 502 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc.

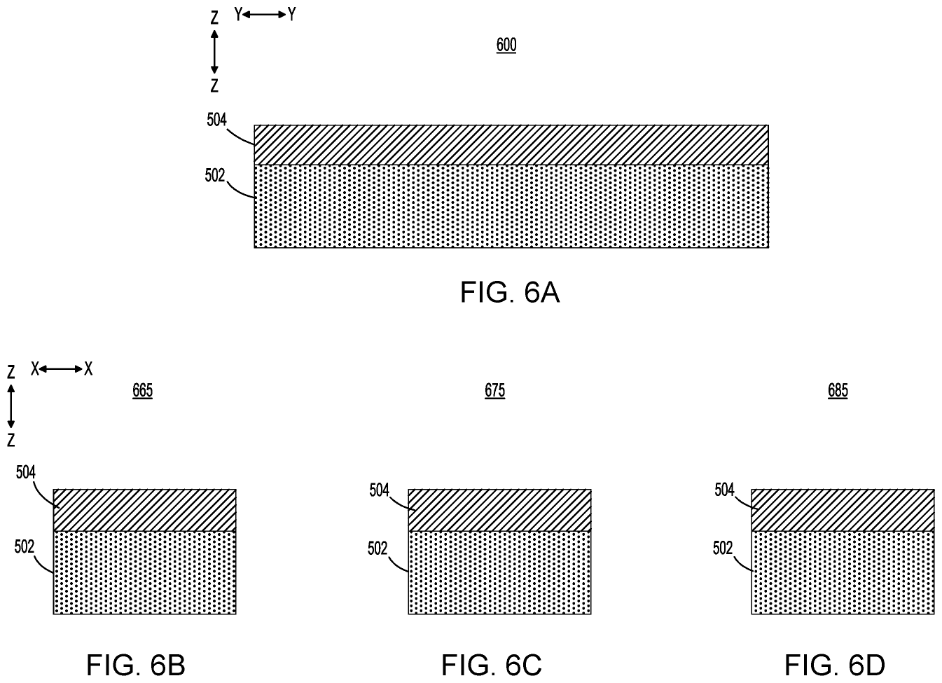

FIGS. 6A-6D show respective cross-sectional views 600, 665, 675 and 685 of the structure of FIGS. 5A-5D following formation of a punch through stopper (PTS) layer 504. The PTS stopper layer 504 may be formed in the substrate 502 through implantation of dopants. The type of dopants implanted is based on the type of structure being formed. For PFET structures, N-type dopants (e.g., phosphorous) are used for the PTS layer 504. For NFET structures, P-type dopants (e.g., boron) are used for the PTS layer 504.

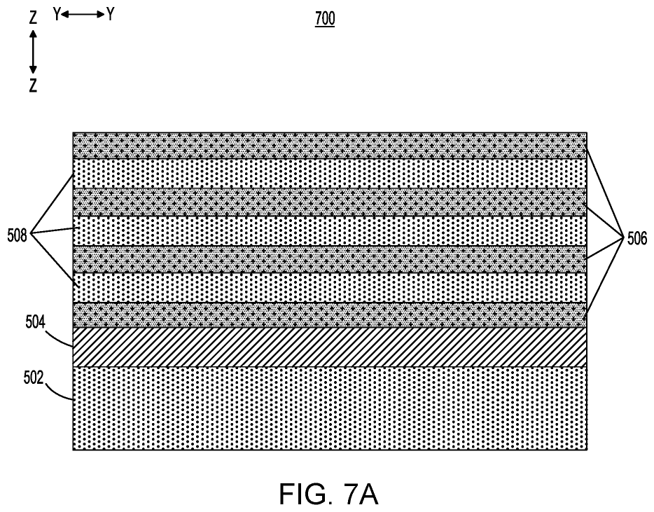

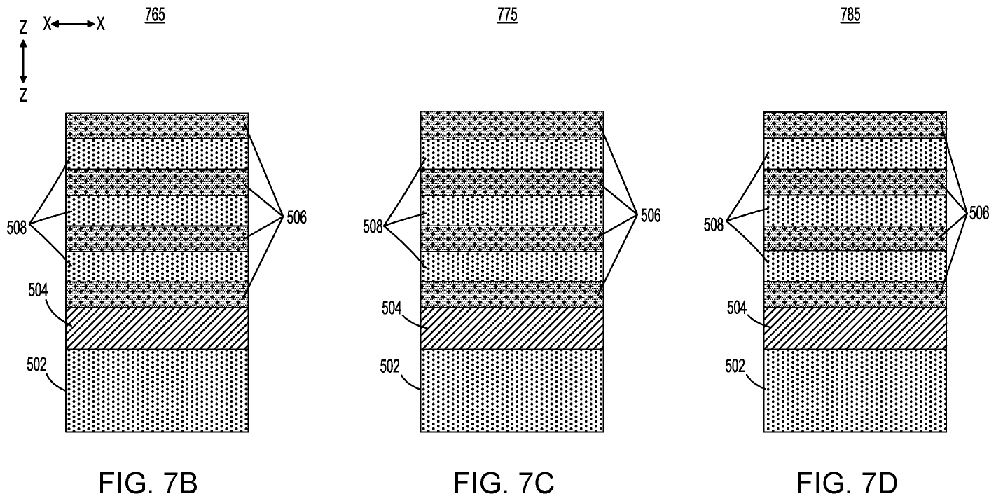

FIGS. 7A-7D show respective cross-sectional views 700, 765, 775 and 785 of the structure of FIGS. 6A-6D following formation of a nanosheet stack over the PTS layer 504, where the nanosheet stack includes sacrificial layers 506 and nanosheet semiconductor layers 508.

The sacrificial layers 506 are formed of a sacrificial material that may be etched or otherwise removed selectively to the nanosheet semiconductor layers 508. The sacrificial layers 506, for example, may be formed of SiGe, where the percentage of Ge is between 15-40%, while the nanosheet semiconductor layers 508 are formed of Si or another suitable material (e.g., a material similar to that used for the substrate 502). Various other combinations of materials may be used for the sacrificial layers 506 and the nanosheet semiconductor layers 508 in other embodiments. Each of the sacrificial layers 506 may have a thickness (in direction Z) in the range of 5-15 nm. Each of the nanosheet semiconductor layers 508 may have a thickness (in direction Z) in the range of 5-15 nm.

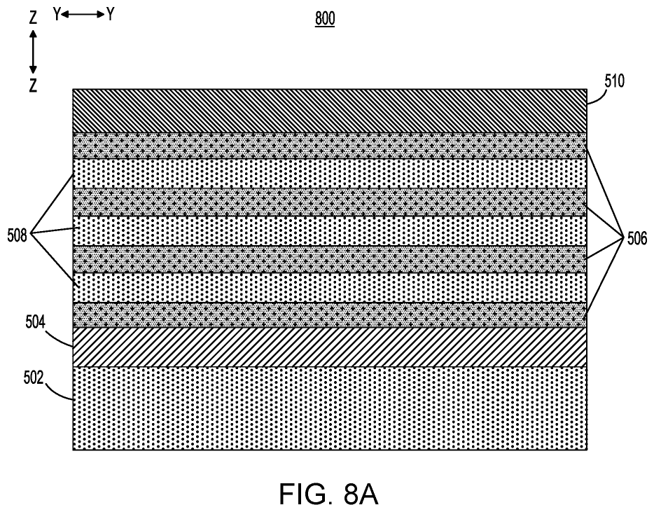

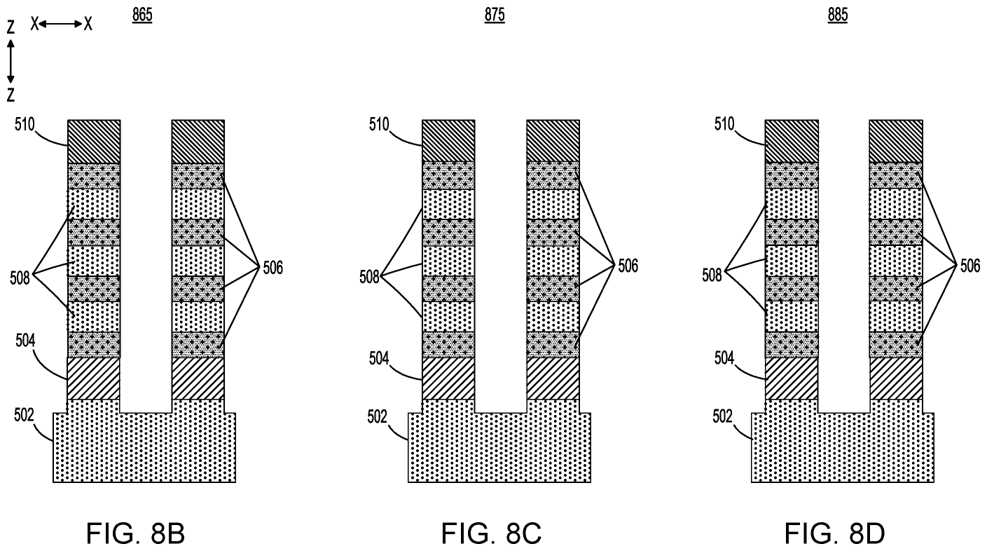

FIGS. 8A-8D show respective cross-sectional views 800, 865, 875 and 885 of the structure of FIGS. 7A-7D following fin formation. A hard mask (HM) layer 510 is first formed over the top of the nanosheet stack, and is then patterned (as shown in FIGS. 8B-8D) to remain in regions where fins are to be formed. An etch process is then performed (e.g., reactive-ion etching (RIE) or another suitable process) to remove exposed portions of the nanosheet stack, exposed portions of the PTS layer 504, and into exposed portions of the substrate 502. The HM layer 510 may be formed of one or more dielectric layers such as oxide layers, nitride layers, or combinations thereof. The HM layer 510 may have a thickness (in direction Z) in the range of 20-50 nm.

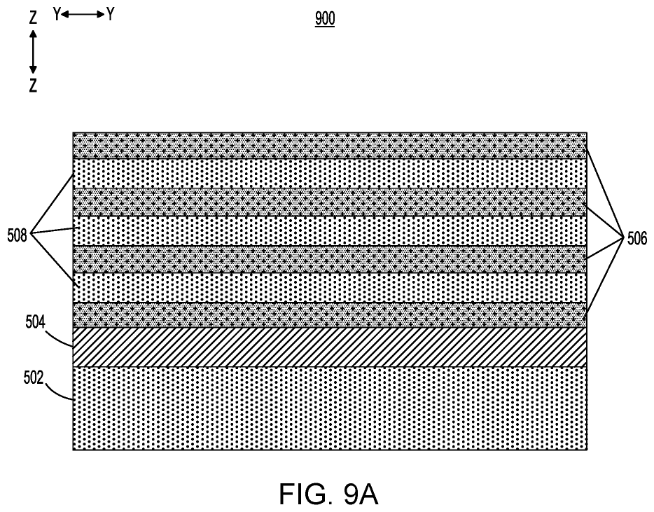

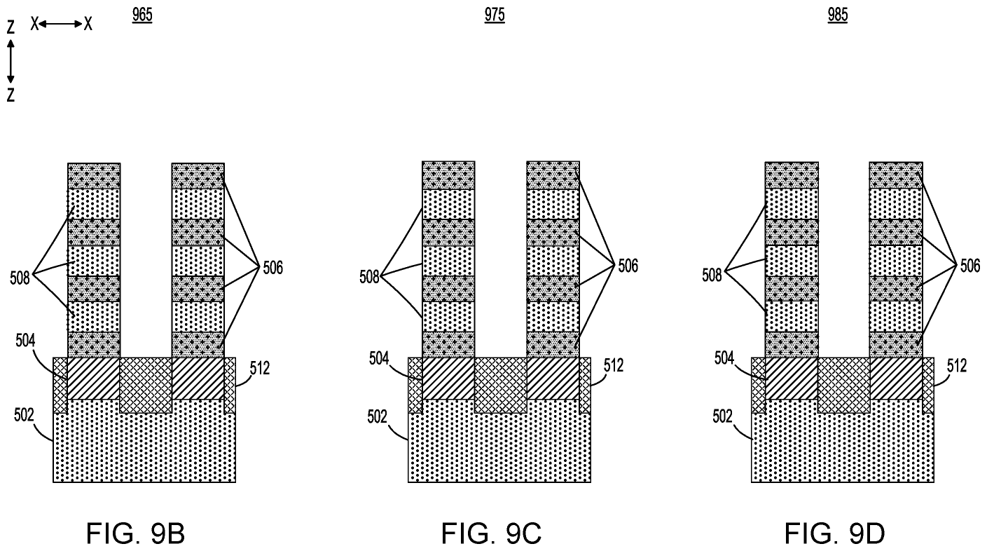

FIGS. 9A-9D show respective cross-sectional views 900, 965, 975 and 985 of the structure of FIGS. 8A-8D following formation of shallow trench isolation (STI) regions 512. The STI regions 512 may be formed of a dielectric material such as silicon dioxide (SiO₂), silicon oxycarbide (SiOC), silicon oxynitride (SiON), etc. The STI regions 512 may have a height (in direction Z) in the range of 20 to 100 nm. Following formation of the STI regions 512, the HM layer 510 may be removed.

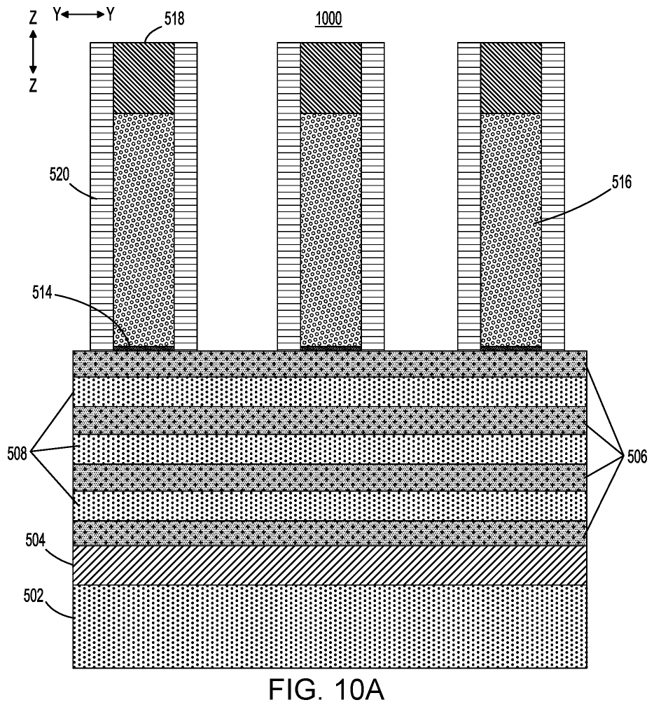

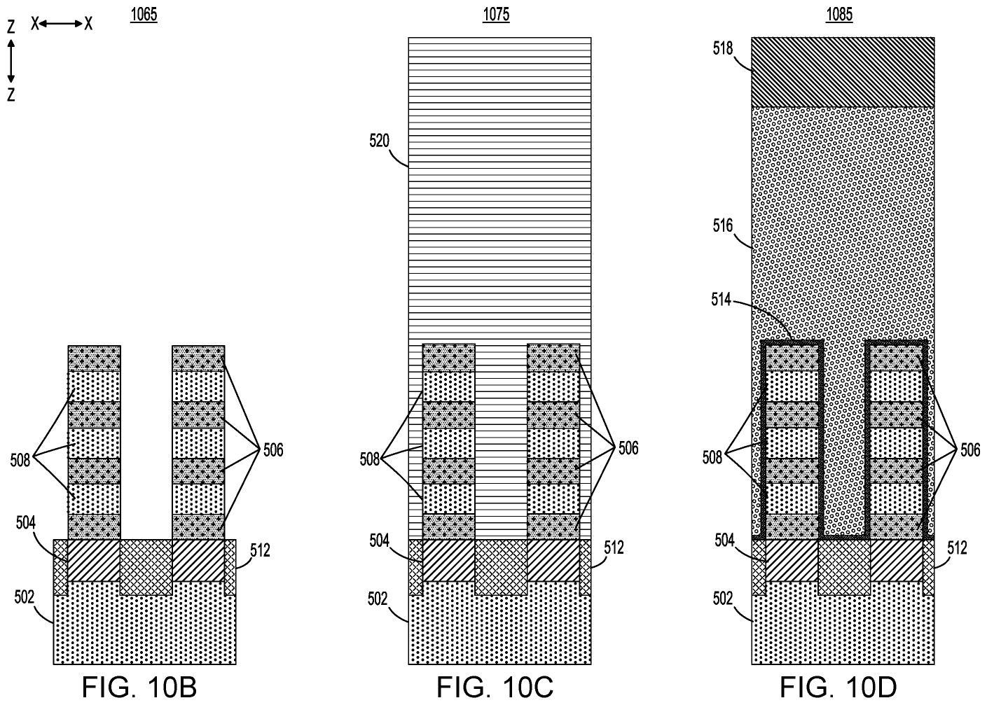

FIGS. 10A-10D show respective cross-sectional views 1000, 1065, 1075 and 1085 of the structure of FIGS. 9A-9D following formation of a dummy oxide layer 514, dummy gate layers 516, HM layer 518, and sacrificial spacers 520. The material of the dummy oxide layer 514 may be formed over the entire structure first, followed by the material for the dummy gate layers 516. The HM layer 518 may then be patterned over the structure, followed by etching to remove exposed portions of the materials of the dummy oxide layer 514 and the dummy gate layers 516. The sacrificial spacers 520 may then be formed on sidewalls of the dummy oxide layer 415, the dummy gate layers 516 and the HM layer 518.

The dummy oxide layer 514 may be formed of any suitable oxide material. The dummy oxide layer 514 may have a uniform thickness in the range of 2-6 nm.

The dummy gate layers 516 may be formed of amorphous silicon (a-Si) or another suitable material such as polysilicon (poly-Si). The dummy gate layers 516 may have a height (in direction Z), as measured from a top surface of the STI regions 512, in the range of 50-200 nm. The dummy gate layers 516 may each have a length (in direction Y) in the range of 10-200 nm.

The HM layer 518 may be formed of one or more dielectric layers, such as oxide layers, nitride layers, or combinations thereof. The HM layer 518 may have a height (in direction Z) in the range of 20-70 nm, and may have a width (in direction Y) which matches the width of the underlying dummy gate layers 516.

The sacrificial spacers 520 may be formed of amorphous silicon germanium (a-SiGe). The sacrificial spacers 520 may have a height that matches that of the dummy gate layers 516, and may have a width (in direction Y) in the range of 5-20 nm.

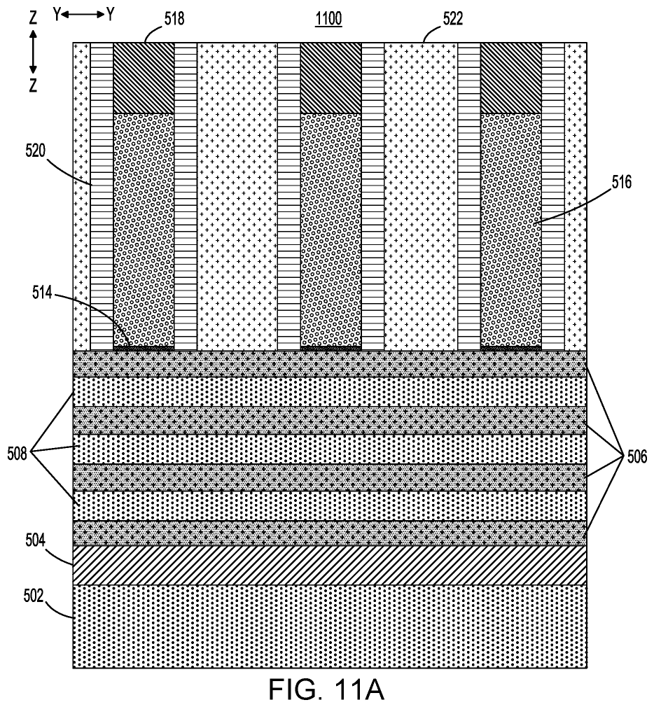

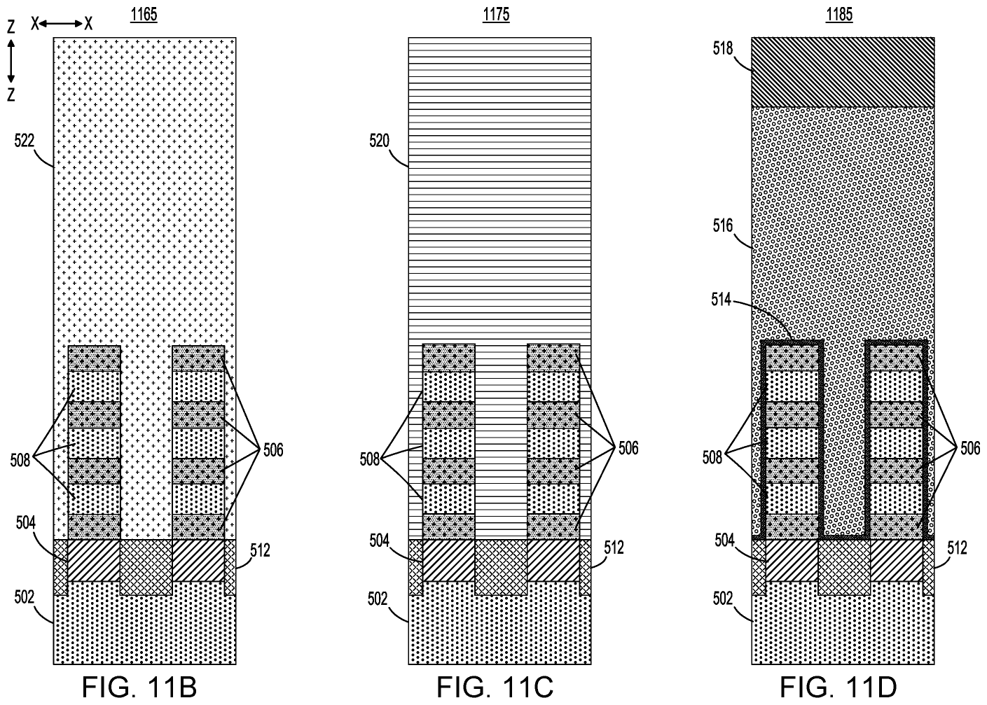

FIGS. 11A-11D show respective cross-sectional views 1100, 1165, 1175 and 1185 of the structure of FIGS. 10A-10D following formation of an interlayer dielectric (ILD) layer 522. Material for the ILD layer 522 may be formed over the structure, followed by planarization (e.g., using chemical mechanical planarization (CMP) or other suitable processing). The ILD layer 522 may be formed of any suitable isolating material, such as SiO₂, SiOC, SiON, etc. In some embodiments, an organic planarization layer (OPL) is formed in place of the ILD layer 522. If an OPL is used, RIE etch-back is used to recess the layer rather than CMP.

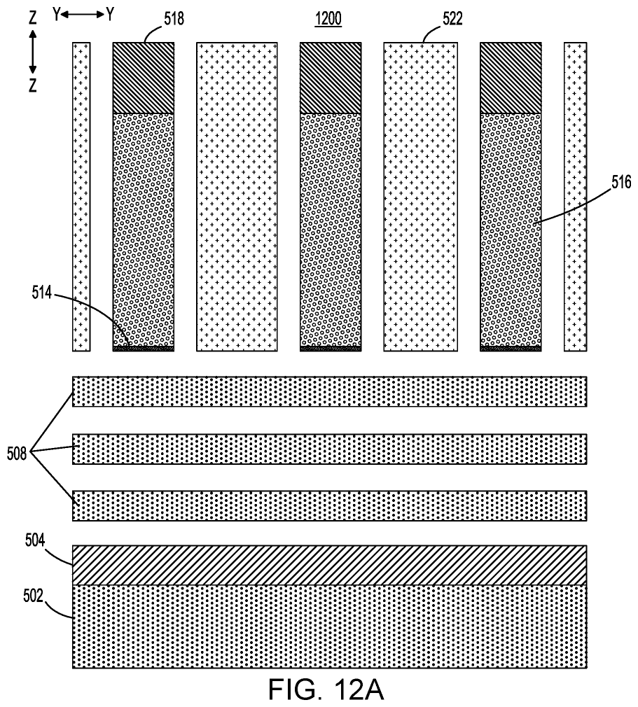

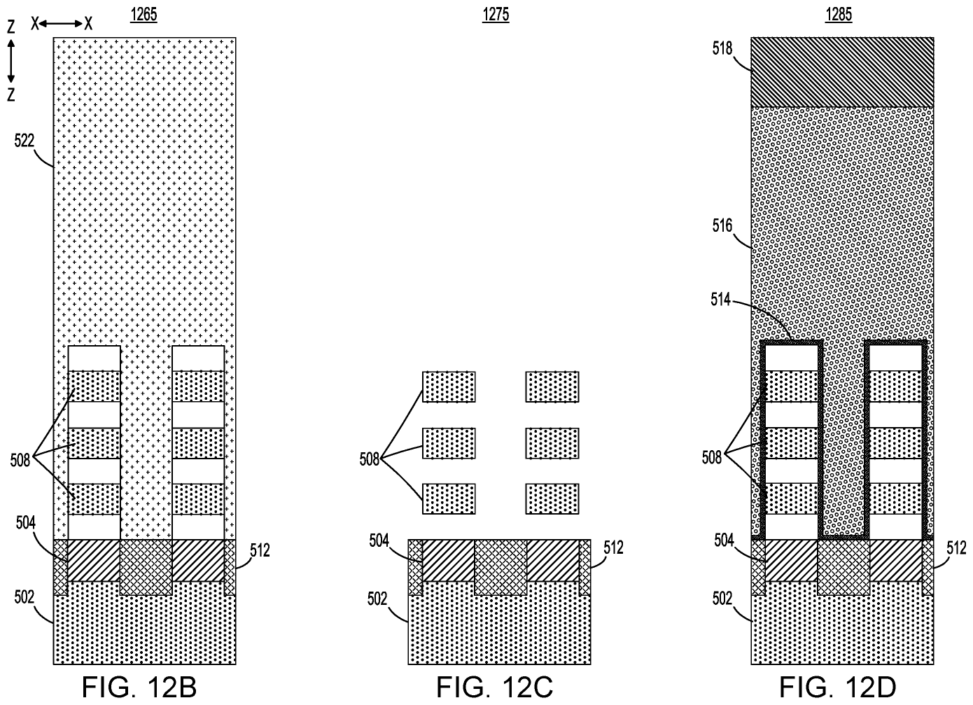

The structure shown in FIGS. 11A-11D may be subject to further processing as described below with respect to FIGS. 12A-22D or FIGS. 23A-32D.

FIGS. 12A-12D show respective cross-sectional views 1200, 1265, 1275 and 1285 of the structure of FIGS. 11A-11D following removal of the sacrificial spacers 520, as well as the sacrificial layers 506 of the nanosheet stack. The sacrificial spacers 520 and the sacrificial layers 506 may be removed, for example, using an etch chemistry including hydrogen chloride (HCl) and chlorine trifluoride (CIF₃).

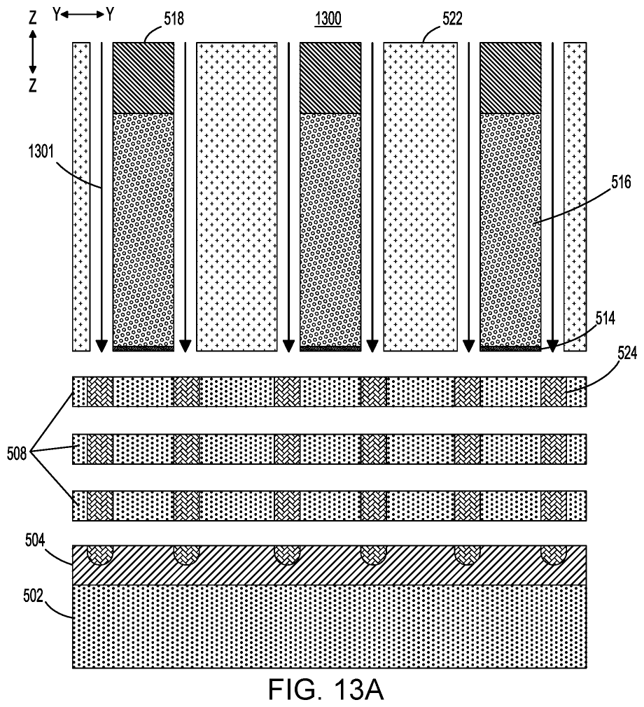

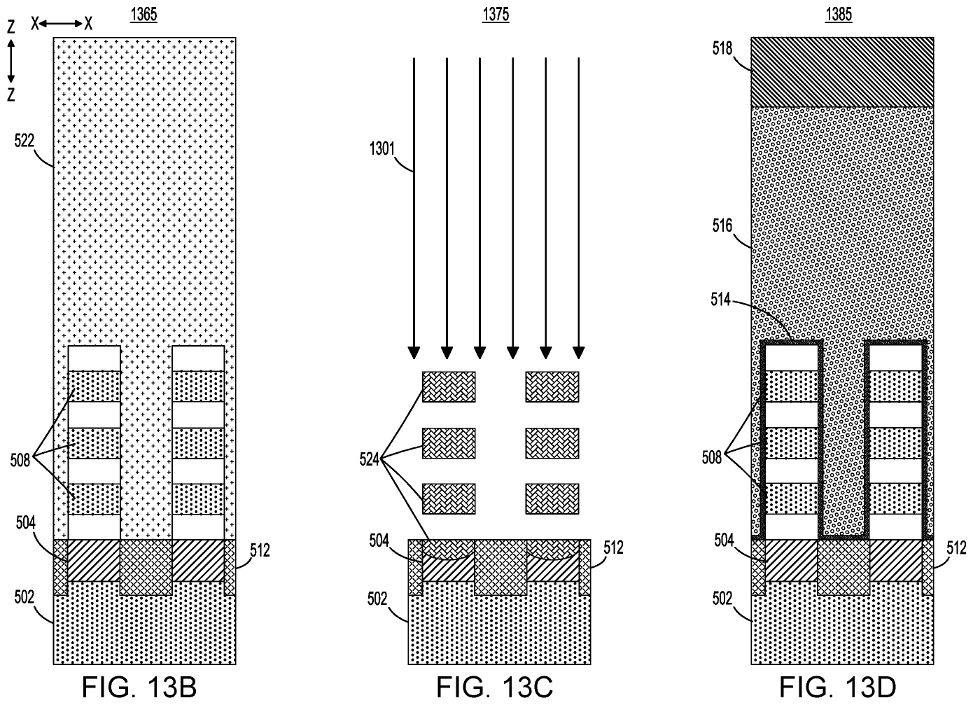

FIGS. 13A-13D show respective cross-sectional views 1300, 1365, 1375 and 1385 of the structure of FIGS. 12A-12D following self-aligned junction implantation 1301 which forms doped regions 524 in exposed portions of the nanosheet semiconductor layers 508 and portions of the PTS layer 504. Various implant species with various energies may be used for the self-aligned junction implantation 1301 to provide lateral straggling control. For PFET devices, p-type dopants (e.g., boron) are used. For NFET devices, n-type dopants (e.g., phosphorus) are used.

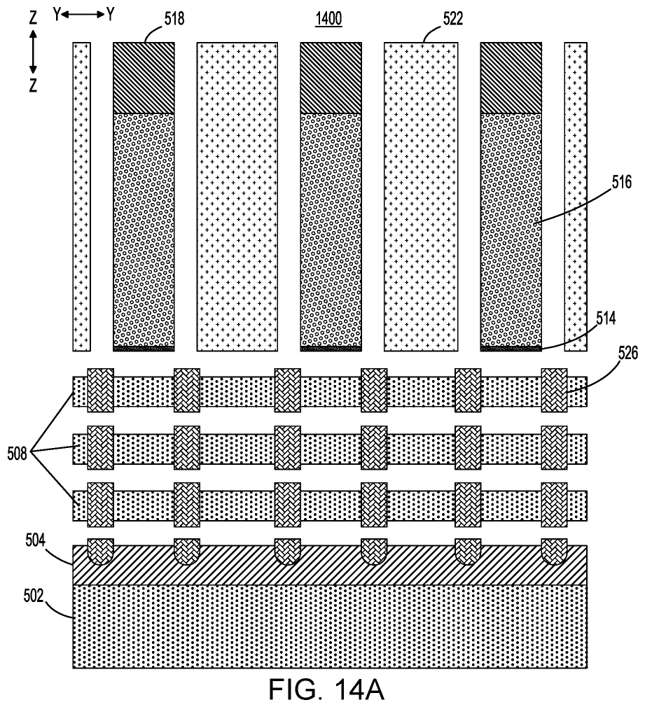

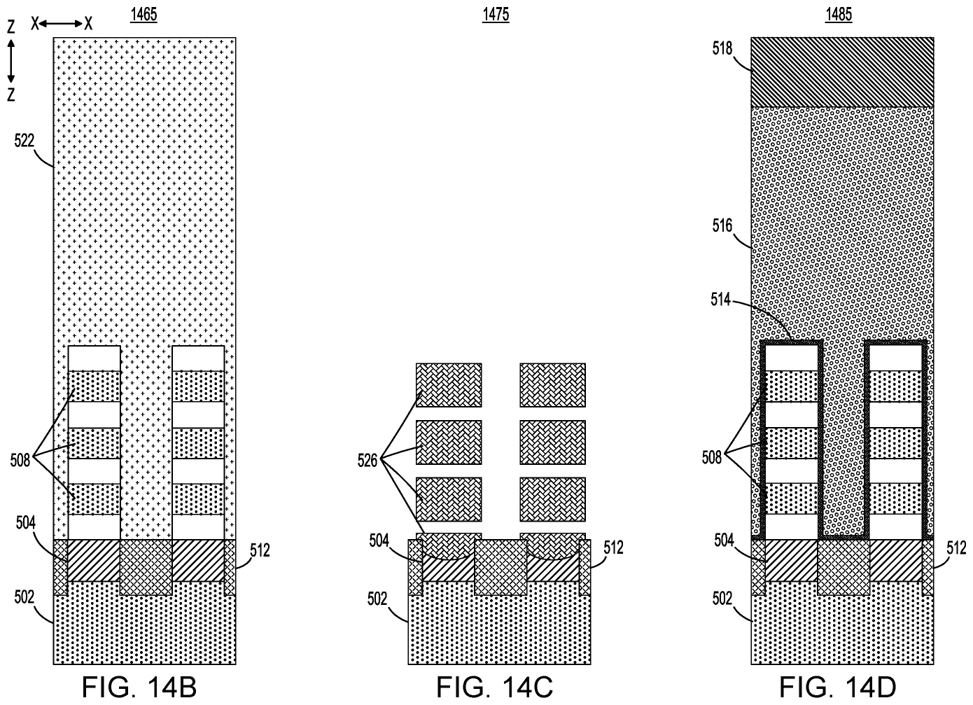

FIGS. 14A-14D show respective cross-sectional views 1400, 1465, 1475 and 1485 of the structure of FIGS. 13A-13D following selective growth of epitaxial layers on the doped regions 524, resulting in larger doped regions 526 as illustrated. The selective growth may be an increase in size of 2-5 nm per side, relative to the original thickness. The selective growth may use a cycled deposition-etching process with preferential growth on the doped regions 524.

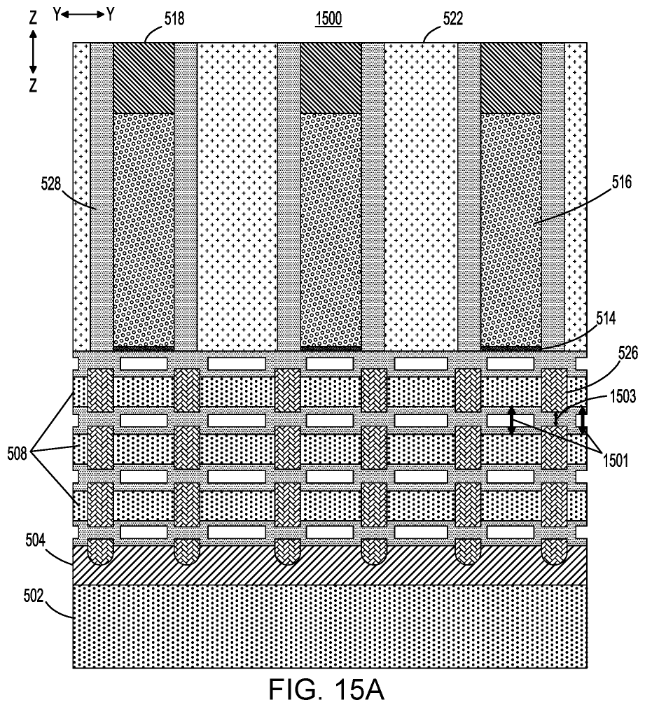

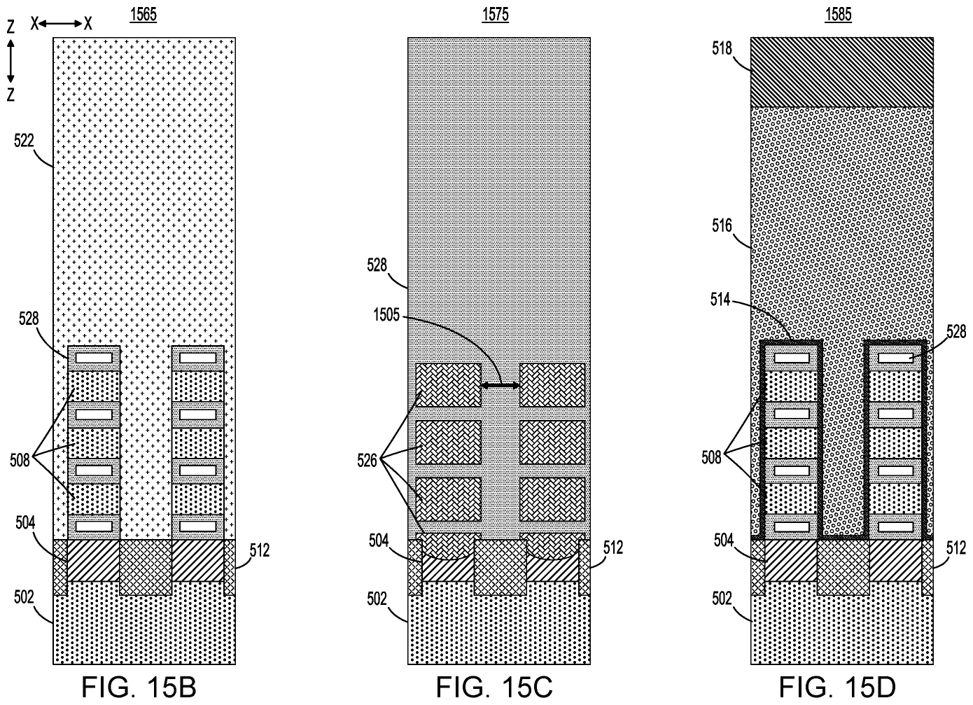

FIGS. 15A-15D show respective cross-sectional views 1500, 1565, 1575 and 1585 of the structure of FIGS. 14A-14D following formation of spacers 528. The spacers 528 include “sidewall” spacers adjacent the dummy gate layers 516, as well as “inner” spacers in spaces between the nanosheet semiconductor layers 508. The spacers 528 may be formed using a conformal deposition process. The spacers 528 may be formed of a low-K material such as silicon oxide (SiO), SiON, SiOC, silicon oxycarbonitride (SiOCN), silicoboron carbonitride (SiBCN), etc. Here, the dimensions 1501 and 1505 are greater than dimension 1503. The dimension 1501 represents the spacing (in direction Z) between adjacent ones of the nanosheet semiconductor layers 508, while dimension 1503 represents the distance (in direction Z) between adjacent ones of the doped regions 526. Dimension 1505 represents the distance (in direction X) between adjacent ones of the doped regions 526. The dimension 1501 may be in the range of 8-15 nm, the dimension 1503 may be in the range of 4-12 nm, and the dimension 1505 may be in the range of 20-150 nm.

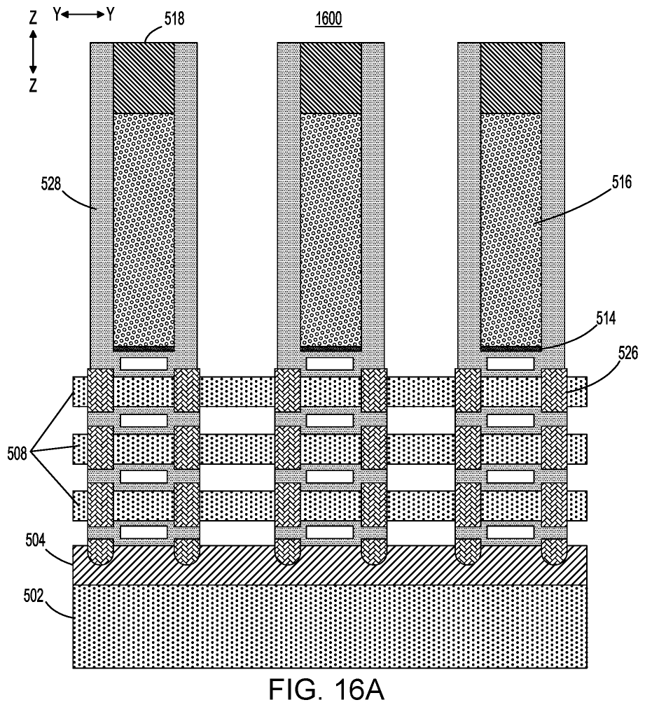

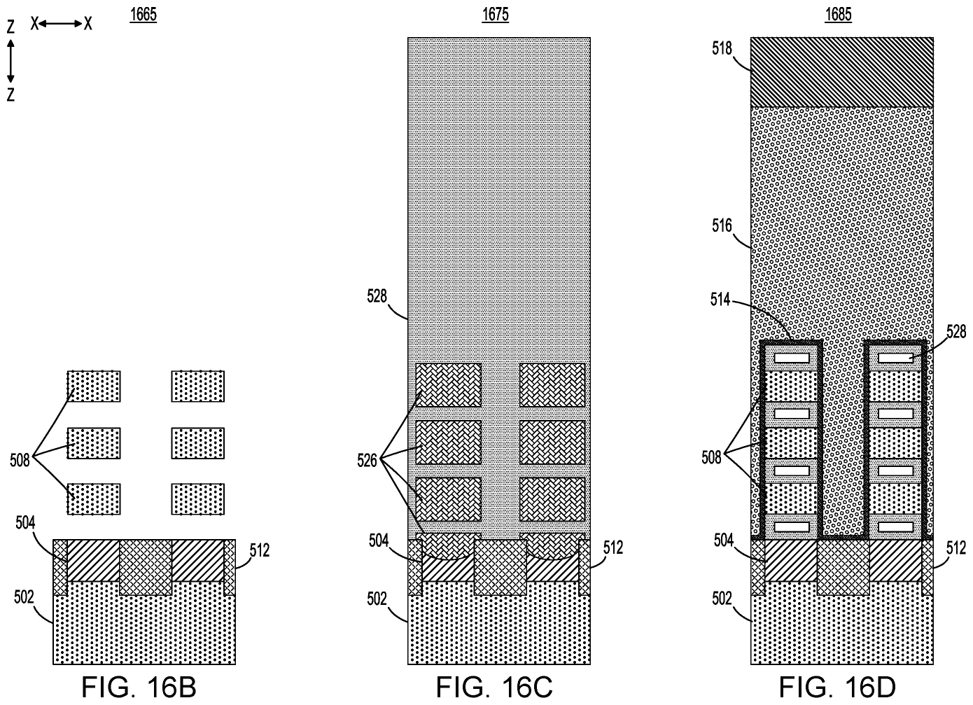

FIGS. 16A-16D show respective cross-sectional views 1600, 1665, 1675 and 1685 of the structure of FIGS. 15A-15D following removal of the ILD layer 522, and following etch-back of portions of the spacers 528. The etch-back of the portions of the spacers 528 may include an isotropic etch process which removes portions of the spacers 528 which surround the nanosheet layers 508 in areas where source/drain regions will be formed (e.g., between the dummy gate layers 516).

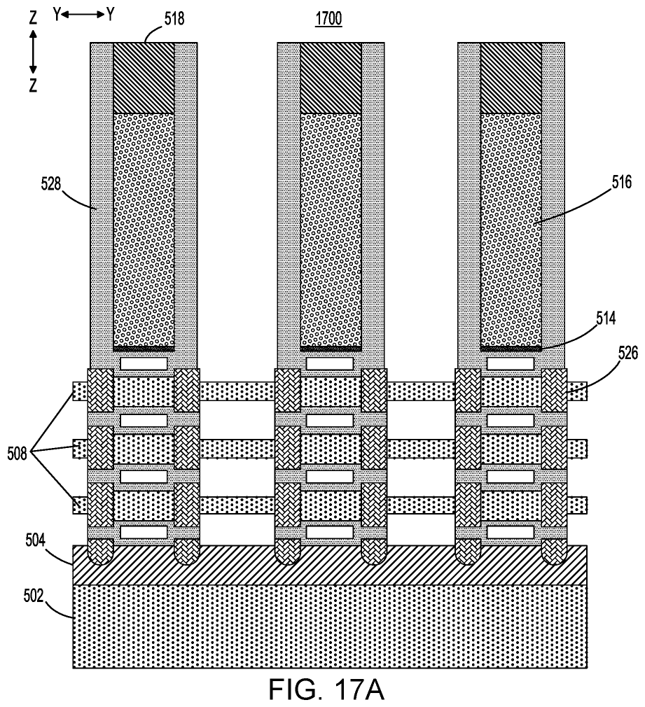

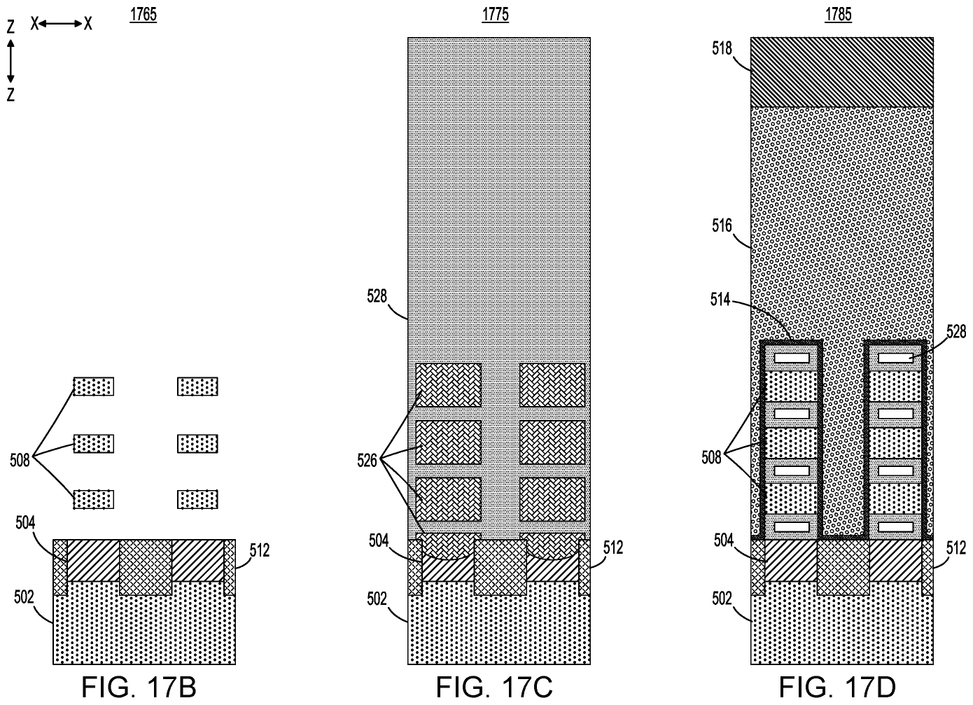

FIGS. 17A-17D show respective cross-sectional views 1700, 1765, 1775 and 1785 of the structure of FIGS. 16A-16D following an optional thinning of the nanosheet semiconductor layers 508 in areas where source/drain regions will be formed (e.g., between the dummy gate layers 516). It should be noted that this step is optional. The amount of thinning may vary as desired. For example, the thickness of the nanosheet layers 508 in between the dummy gate layers 516 may be in the range of 3-13 nm, while the thickness of the nanosheet semiconductor layers 508 that are in the gate region (e.g., underneath the dummy gate layers 516) may be in the range of 5-15 nm.

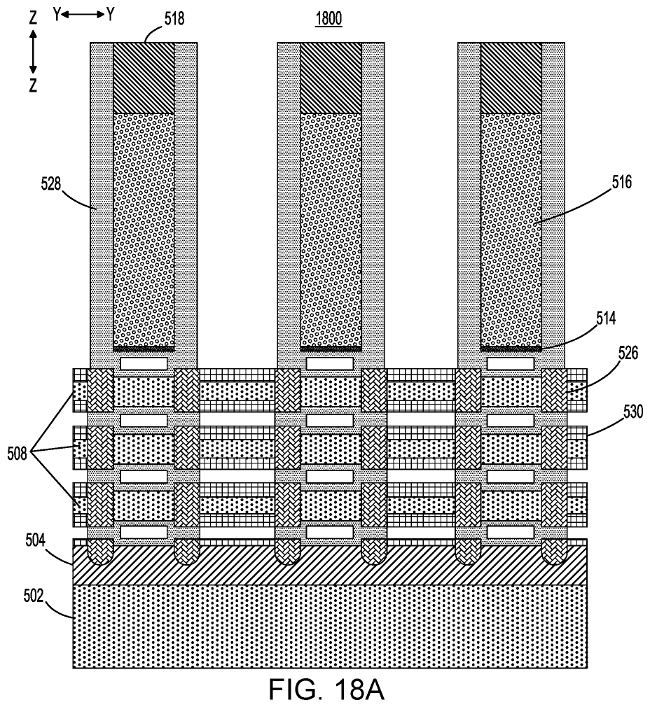

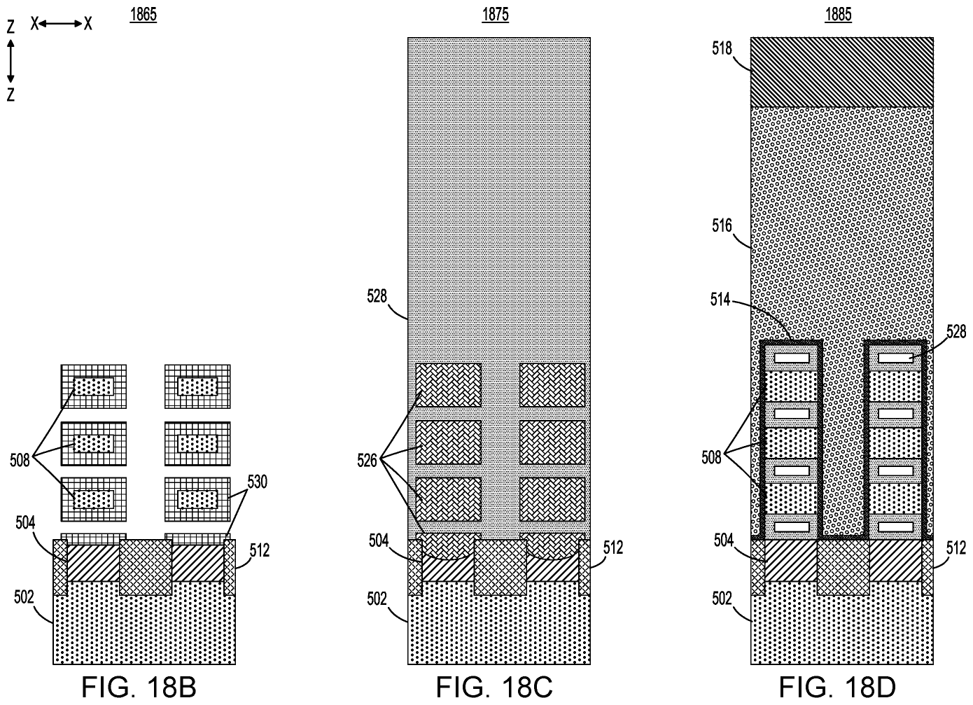

FIGS. 18A-18D show respective cross-sectional views 1800, 1865, 1875 and 1885 of the structure of FIGS. 17A-17D following formation of cladded source/drain epitaxy regions 530 surrounding exposed portions of the nanosheet semiconductor layers 508. The cladded source/drain epitaxy regions 530 may be formed using an epitaxial growth process. In some embodiments, the epitaxy process includes in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. The cladded source/drain epitaxy regions 530 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI). Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³. The cladded source/drain epitaxy regions 530 may have a thickness in the range of 3-10 nm.

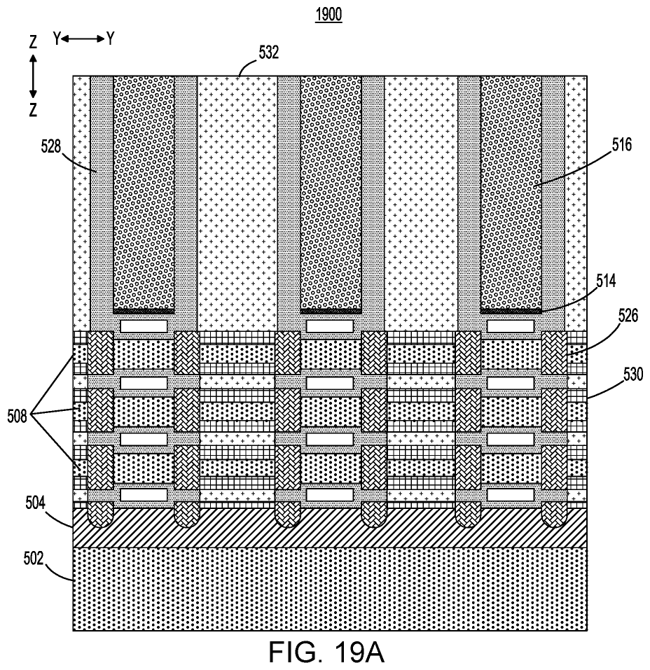

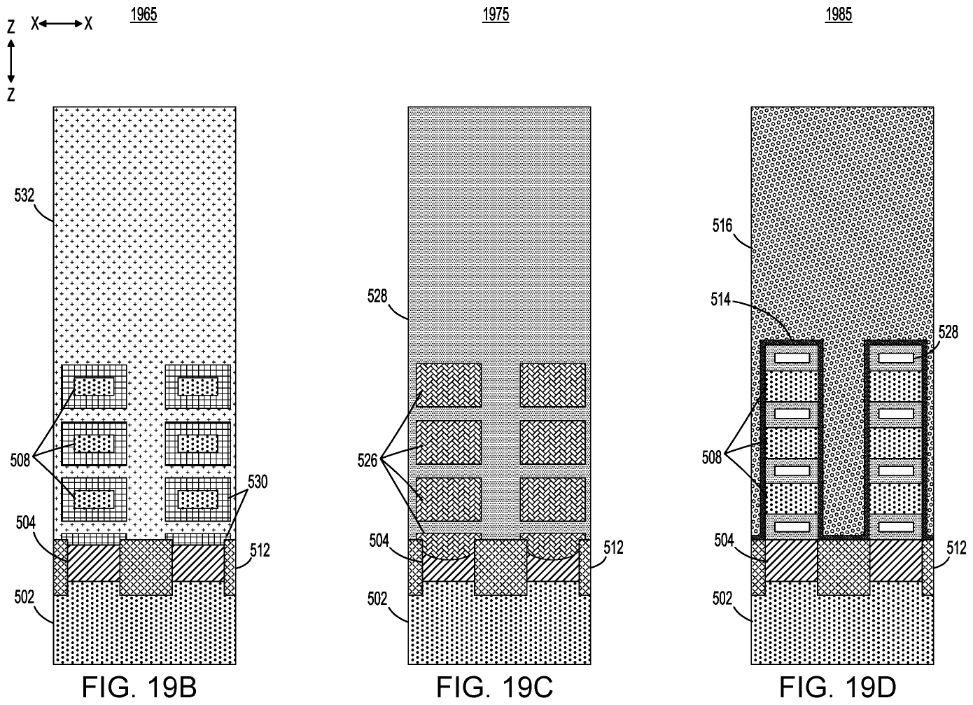

FIGS. 19A-19D show respective cross-sectional views 1900, 1965, 1975 and 1985 of the structure of FIGS. 18A-18D following formation of an ILD layer 532. The ILD layer 532 may be formed of similar materials and with similar sizing as the ILD layer 522. After the ILD layer 532 is formed, the structure may be planarized (e.g., using CMP or other suitable processing) to remove the HM layer 518 and to expose the underlying dummy gate layers 516.

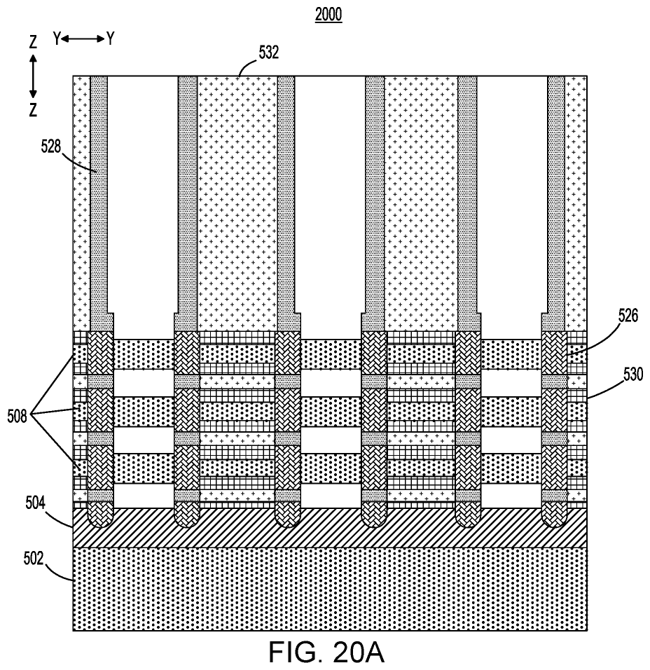

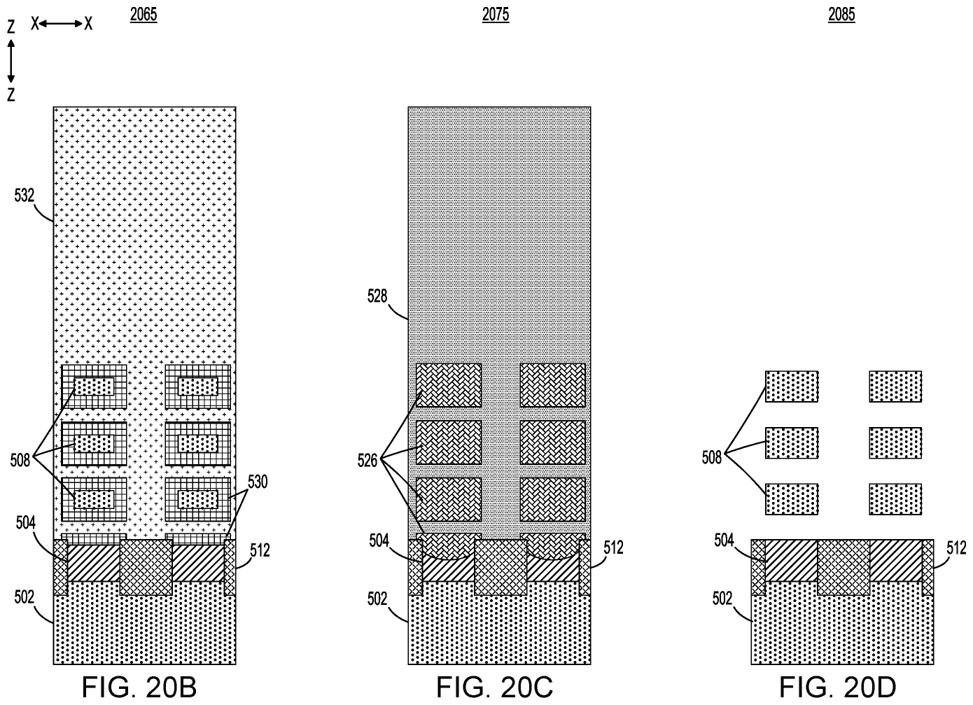

FIGS. 20A-20D show respective cross-sectional views 2000, 2065, 2075 and 2085 of the structure of FIGS. 19A-19D following removal of the dummy gate layers 516, the dummy oxide layer 514, and an isotropic etch-back of the spacers 528.

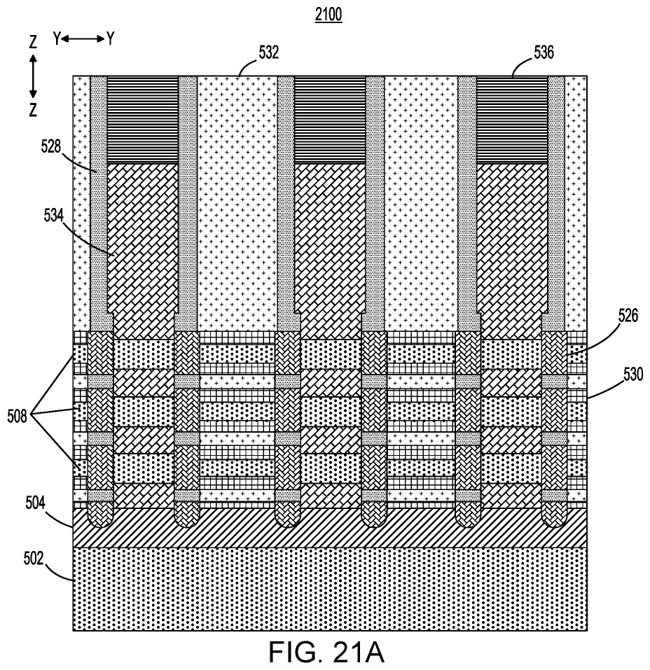

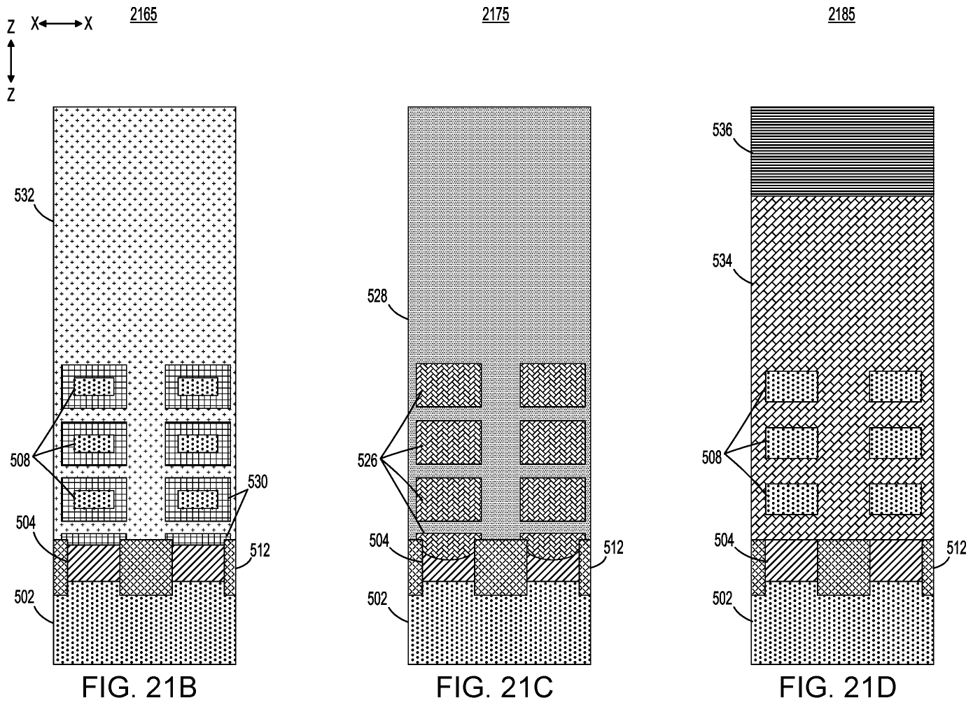

FIGS. 21A-21D show respective cross-sectional views 2100, 2165, 2175 and 2185 of the structure of FIGS. 20A-20D following formation of a gate stack 534 and self-aligned contact (SAC) capping layers 536.

The gate stack 534 may include a gate dielectric layer and a gate conductor layer. The gate dielectric layer may include a high-k dielectric material. Examples of high-k dielectric materials include but are not limited to metal oxides such as hafnium oxide (HfO₂), hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). For nFET devices, the WFM for the gate conductor may be titanium (Ti), aluminum (Al), titanium aluminum (TiAl), titanium aluminum carbon (TiAIC), a combination of Ti and Al alloys, a stack which includes a barrier layer (e.g., of titanium nitride (TiN) or another suitable material) followed by one or more of the aforementioned WFM materials, etc. For pFET devices, the WFM for the gate conductor may be TiN, tantalum nitride (TaN), or another suitable material. In some embodiments, the pFET WFM may include a metal stack, where a thicker barrier layer (e.g., of TiN, TaN, etc.) is formed followed by a WFM such as Ti, Al, TiAl, TiAIC, or any combination of Ti and Al alloys. It should be appreciated that various other materials may be used for gate conductors as desired.

The SAC capping layers 536 may be formed of SiN, SiC, aluminum oxide (AlOₓ), etc. The SAC capping layers 536 may have a height (in direction Z) in the range of 10-30 nm.

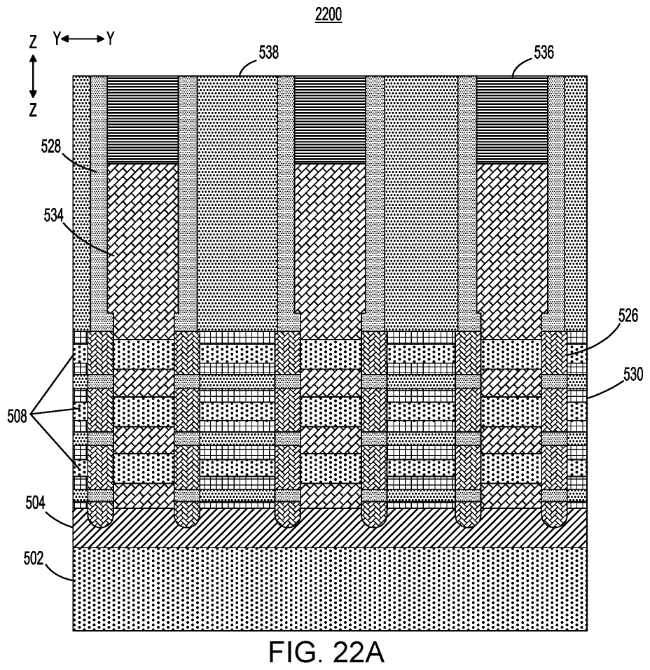

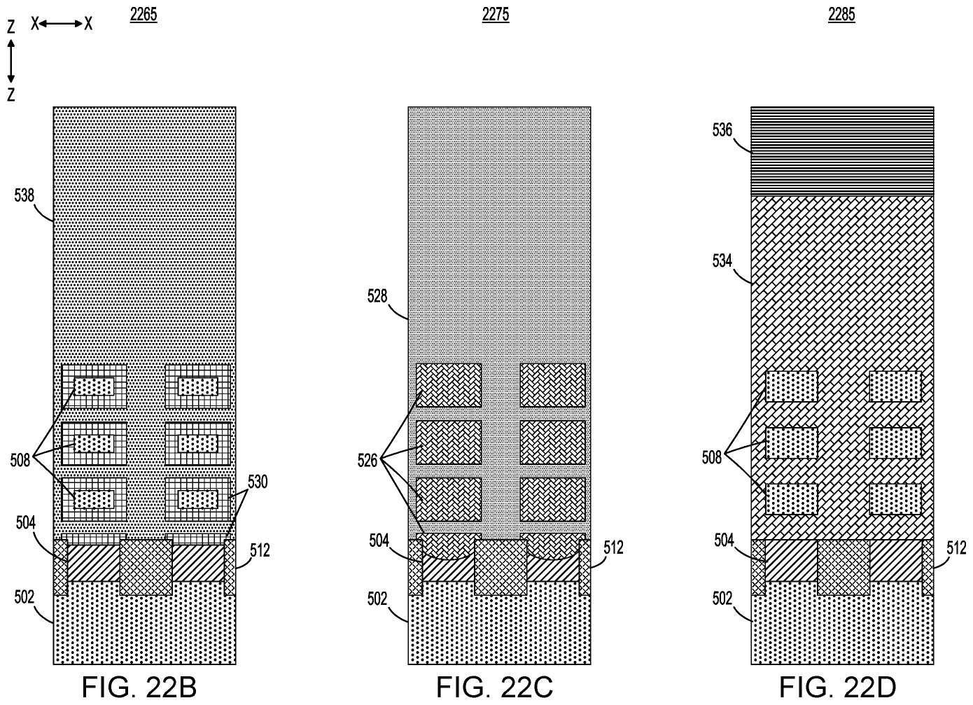

FIGS. 22A-22D show respective cross-sectional views 2200, 2265, 2275 and 2285 of the structure of FIGS. 21A-21D following formation of wrap-all-around contacts 538. The wrap-all-around contacts 538 may be formed by removing portions of the ILD layer 532 to form openings (e.g., in the regions shown in the cross-sectional views 2200 of FIG. 22A and 2265 of FIG. 22B), and then contact materials is deposited in the openings followed by planarization (e.g., using CMP or other suitable processing). The contact material may include a silicide layer such as titanium (Ti), nickel (Ni), nickel platinum (NiPt), etc., a metal adhesion layer (e.g., such as TiN) and a low resistance metal such as tungsten (W), ruthenium (Ru), cobalt (Co) or another suitable material. The wrap-all-around contacts 538 advantageously are formed surrounding the cladded source/drain epitaxy regions 530 which are formed around portions of the nanosheet semiconductor layers 508 between the gate regions.

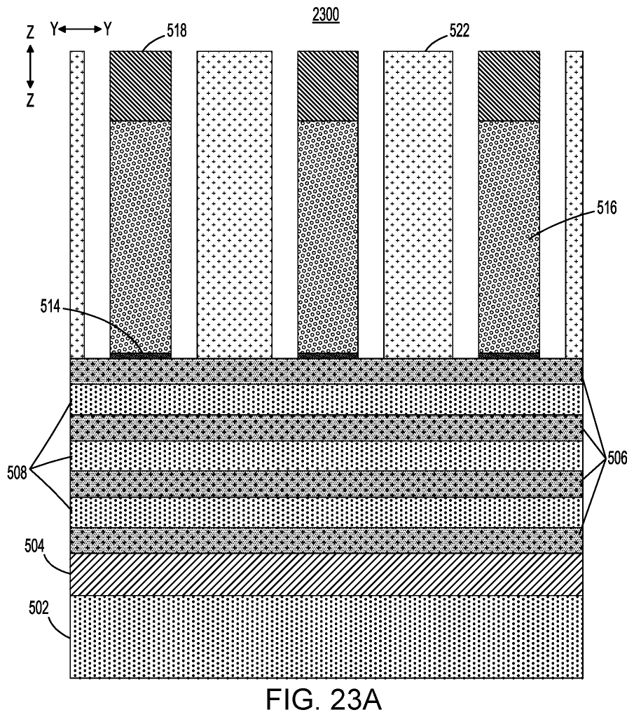

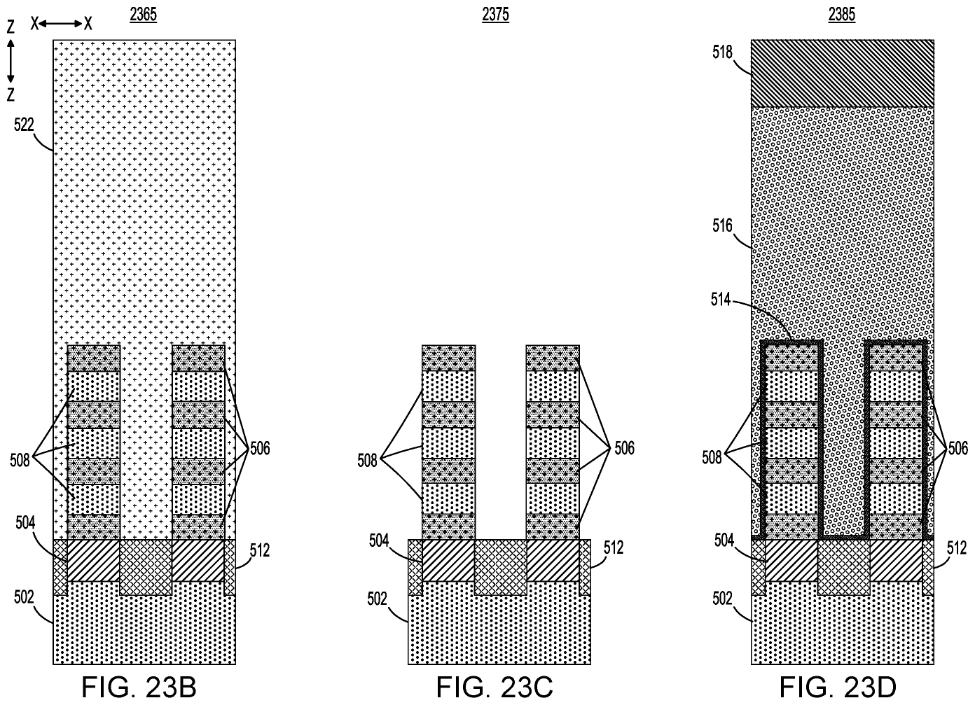

FIGS. 23A-23D show respective cross-sectional views 2300, 2365, 2375 and 2385 of the structure of FIGS. 11A-11D following removal of the sacrificial spacers 520. In the structure described above with respect to FIGS. 11A-11D the sacrificial spacers 520 are made of a-SiGe to match the material (e.g., SiGe) of the sacrificial layers 506 in the nanosheet stack, such that both the sacrificial spacers 520 and the sacrificial layers 506 may be removed with the same etch chemistry. In the structure of FIGS. 23A-23D, the sacrificial spacers 520 are made of a different material than the sacrificial layers 506 of the nanosheet stack and are not removed using the same etch chemistry. For example, the sacrificial spacers 520 may be formed of a dielectric such as SiO, AlOₓ or titanium oxide (TiOₓ).

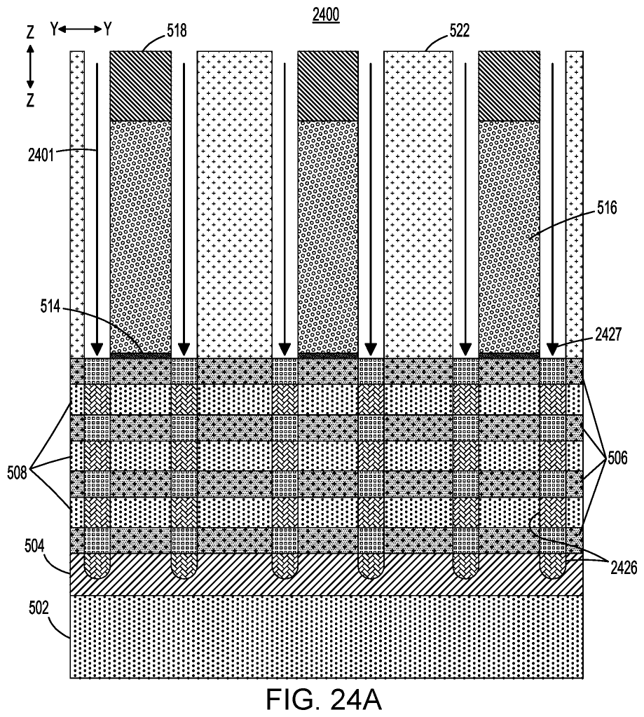

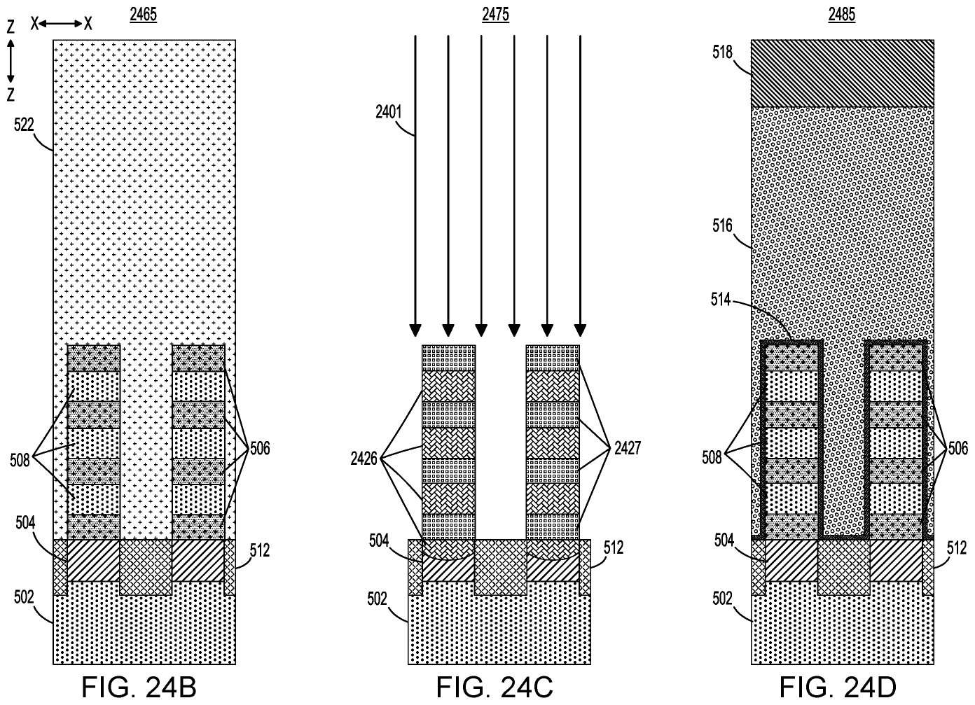

FIGS. 24A-24D show respective cross-sectional views 2400, 2465, 2475 and 2485 of the structure of FIGS. 23A-23D following self-aligned junction implantation 2401, which forms doped regions 2426 in exposed portions of the nanosheet semiconductor layers 508 and portions of the PTS layer 504, as well as doped regions 2427 in exposed portions of the sacrificial layers 506. Various implant species with various energies may be used for the self-aligned junction implantation 1401 to provide lateral straggling control, such as those described above in conjunction with FIGS. 12A-12D.

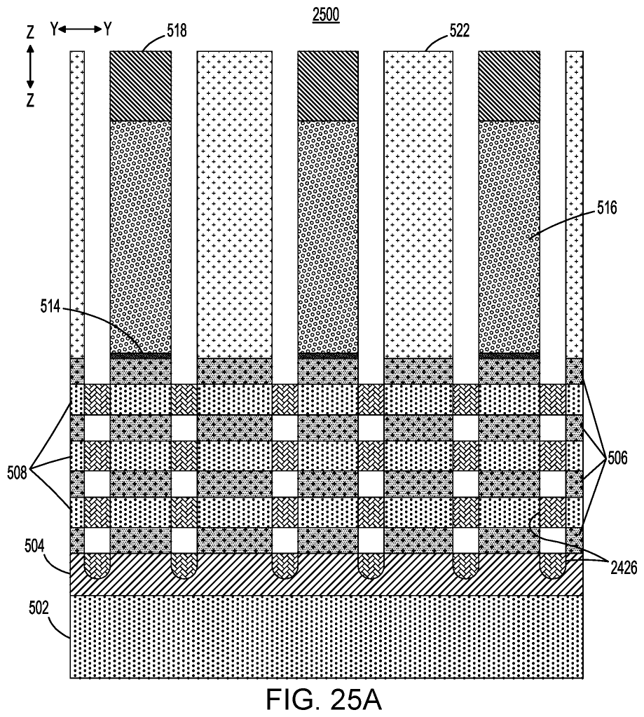

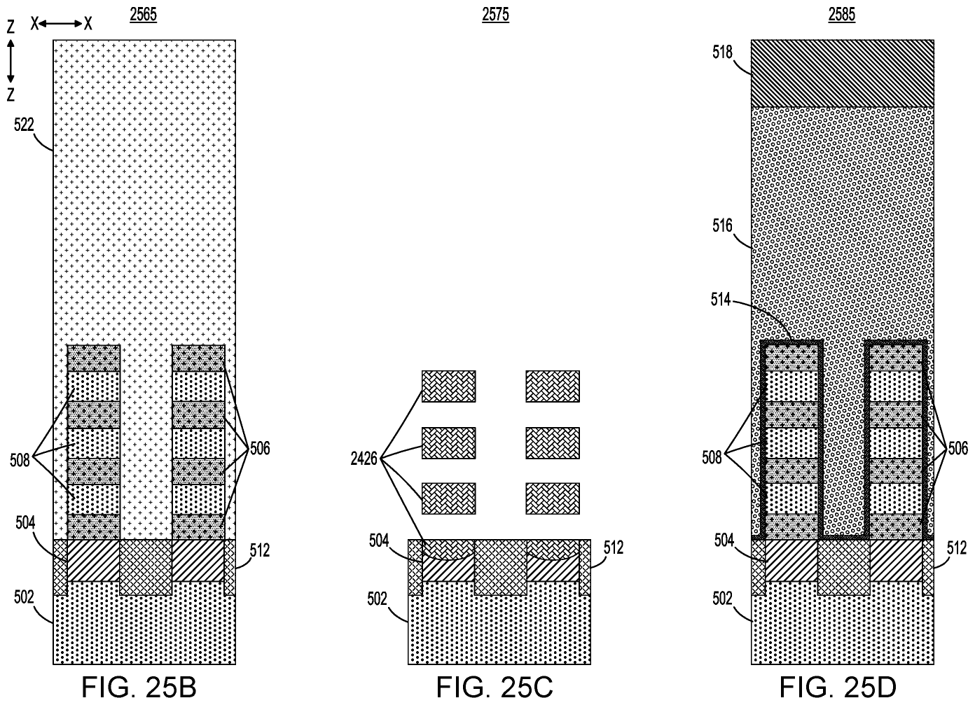

FIGS. 25A-25D show respective cross-sectional views 2500, 2565, 2575 and 2585 of the structure of FIGS. 24A-24D following removal of the doped regions 2427. The doped regions 2427 are removed selective to the doped regions 2426 using an isotropic etch process.

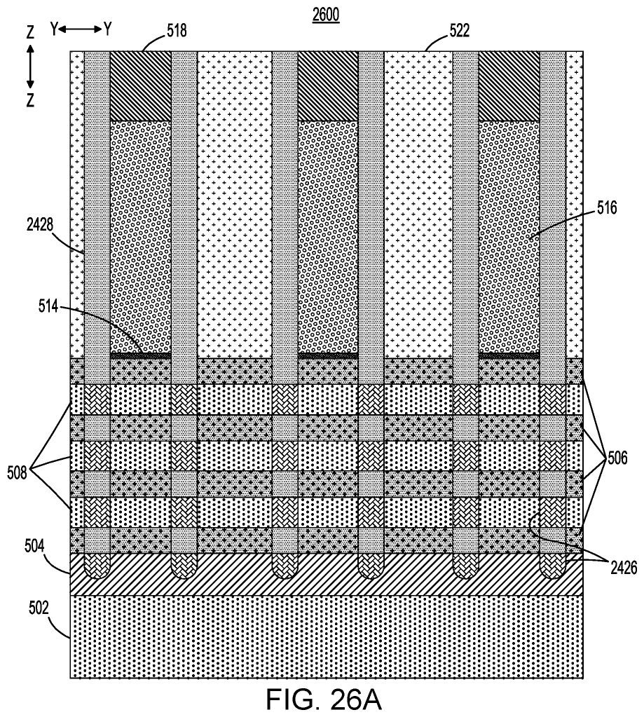

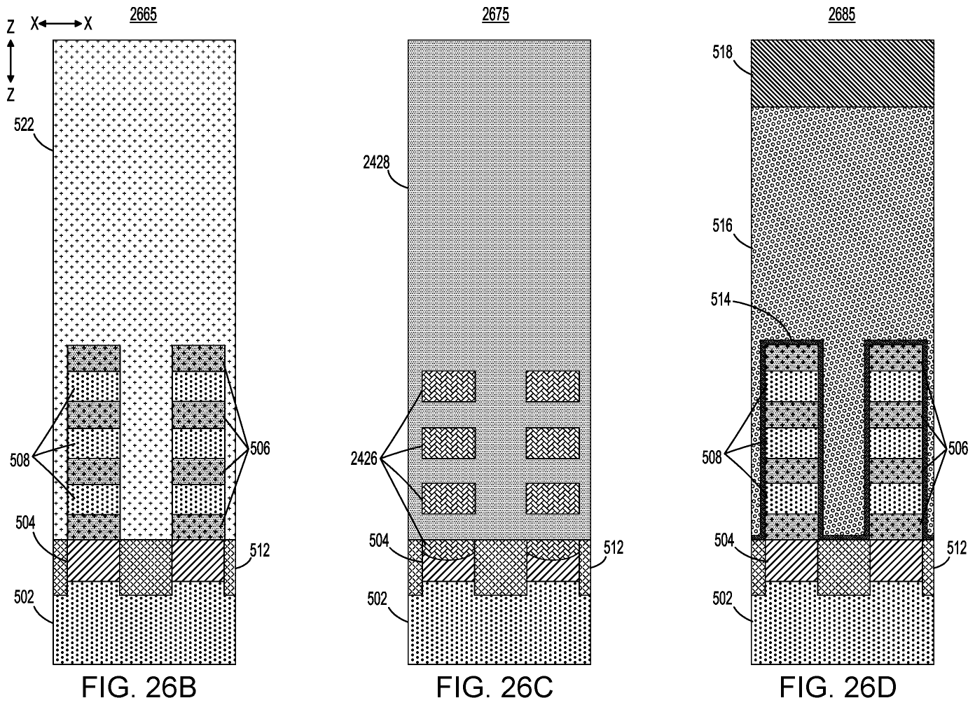

FIGS. 26A-26D show respective cross-sectional views 2600, 2665, 2675 and 2685 of the structure of FIGS. 25A-25D following formation of spacers 2428. The spacers 2428 include “sidewall” spacers adjacent the dummy gate layers 516, as well as “inner” spacers in spaces between the nanosheet semiconductor layers 508. The spacers 2428 may be formed using a conformal deposition process. The spacers 2428 may be formed of a low-K material similar to that of the spacers 528.

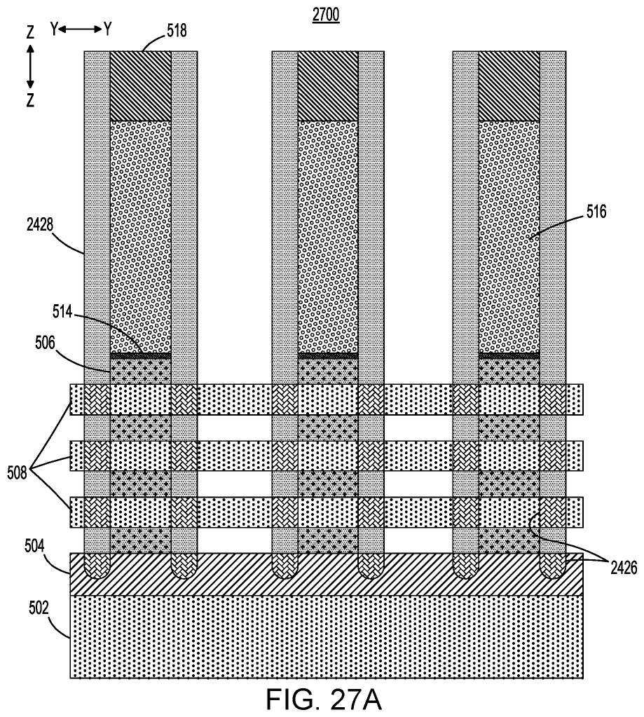

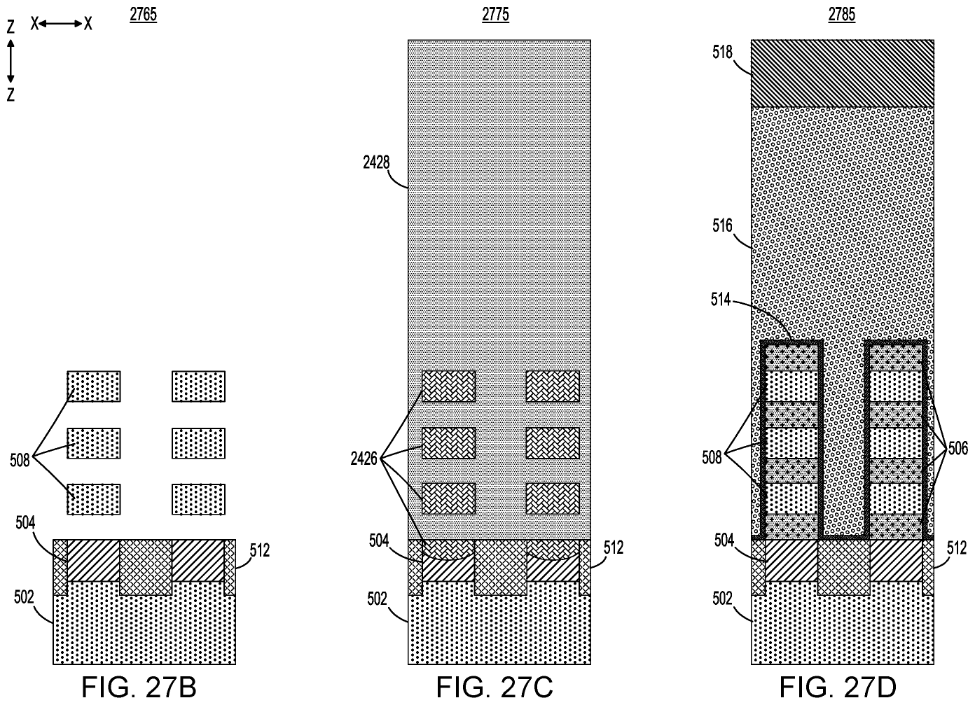

FIGS. 27A-27D show respective cross-sectional views 2700, 2765, 2775 and 2785 of the structure of FIGS. 26A-26D following removal of the ILD layer 522 and removal of exposed portions of the sacrificial layers 506.

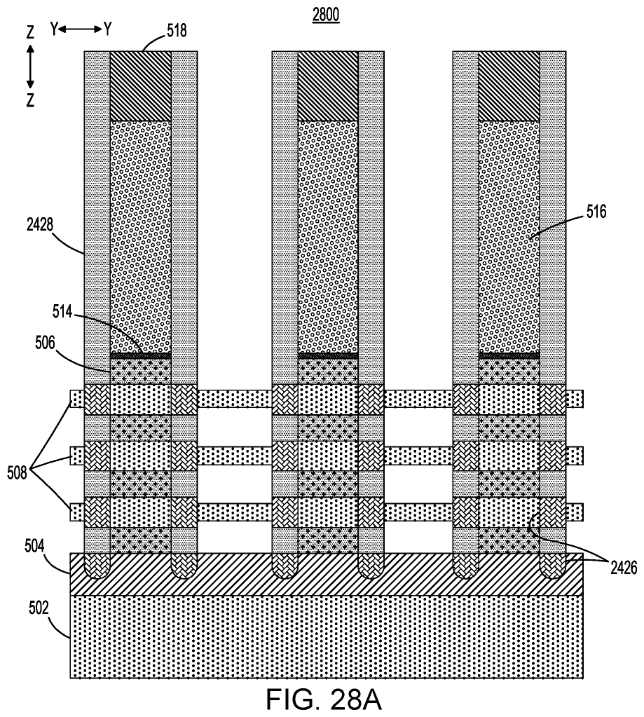

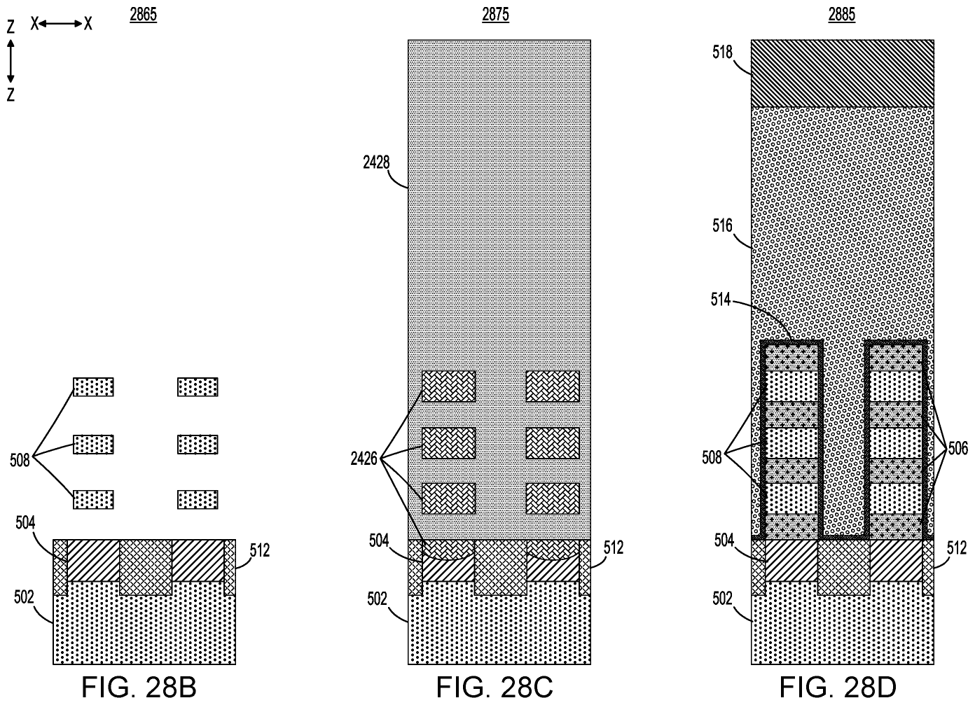

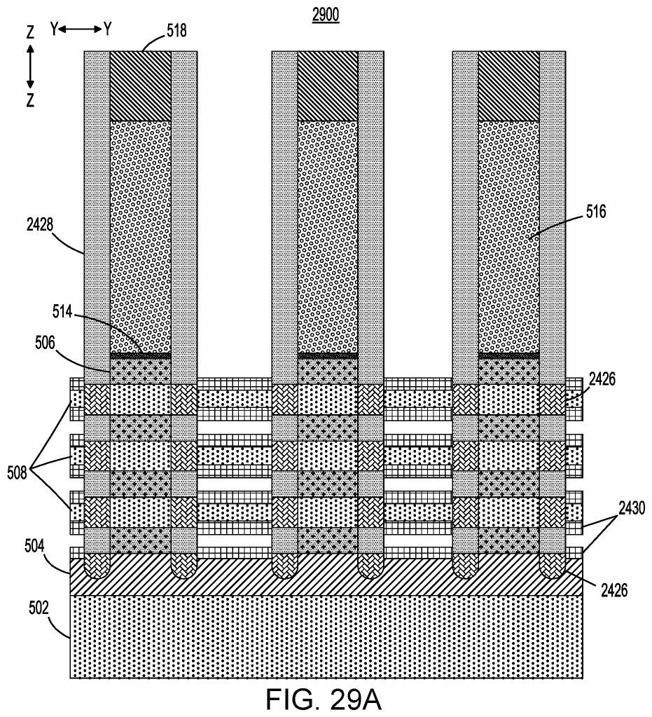

FIGS. 28A-28D show respective cross-sectional views 2800, 2865, 2875 and 2885 of the structure of FIGS. 27A-27D following an optional thinning of the nanosheet layers 508 of the nanosheet stack in areas where source/drain regions will be formed (e.g., between the dummy gate layers 516). It should be noted that this step is optional. The amount of thinning may be similar to that described above with respect to FIGS. 17A-17D.

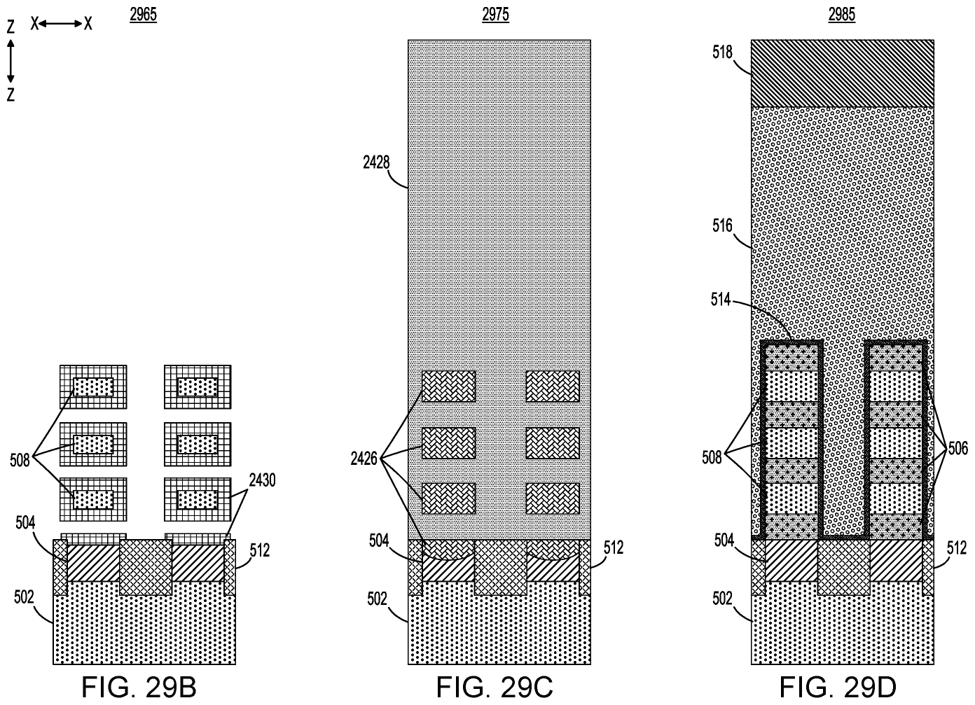

FIGS. 29A-29D show respective cross-sectional views 2900, 2965, 2975 and 2985 of the structure of FIGS. 28A-28D following formation of cladded source/drain epitaxy regions 2430 surrounding exposed portions of the nanosheet layers 508. The cladded source/drain epitaxy regions 2430 may be formed of similar materials, and with similar processing and sizing as that described above with respect to cladded source/drain epitaxy regions 530.

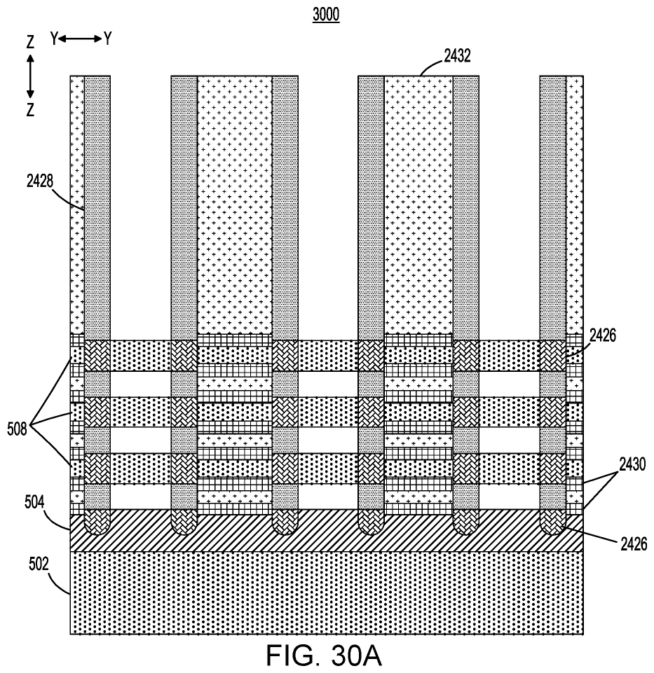

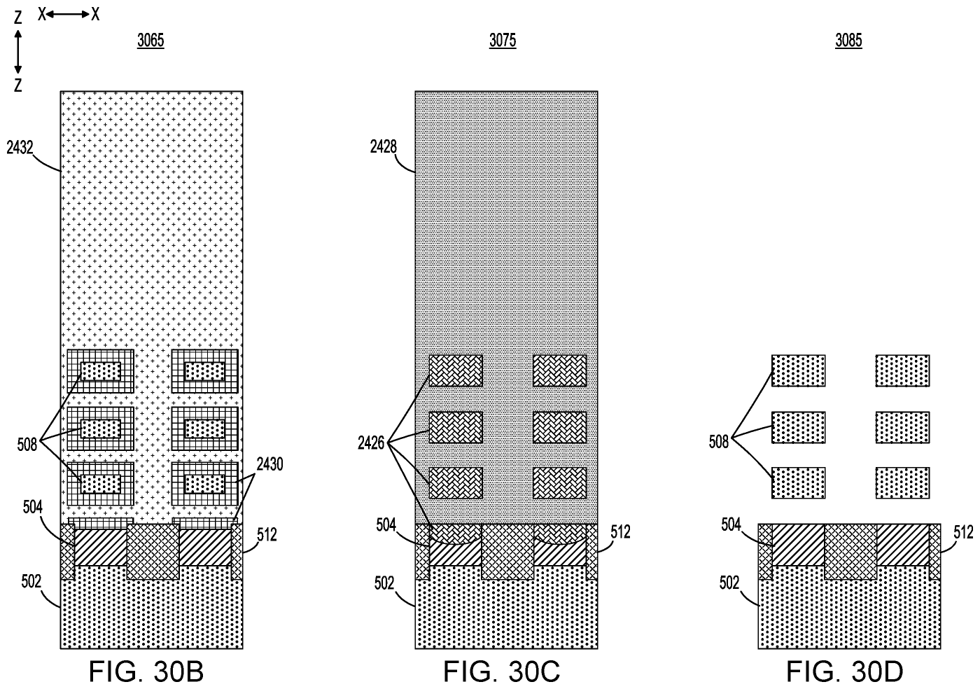

FIGS. 30A-30D show respective cross-sectional views 3000, 3065, 3075 and 3085 of the structure of FIGS. 29A-29D following formation of an ILD layer 2432, and following removal of the HM layer 518, the dummy gate layers 516, the dummy oxide layer 514 and remaining portions of the sacrificial layers 506. The ILD layer 2432 may be formed of similar materials, and with similar processing and sizing as that described above with respect to ILD layer 532.

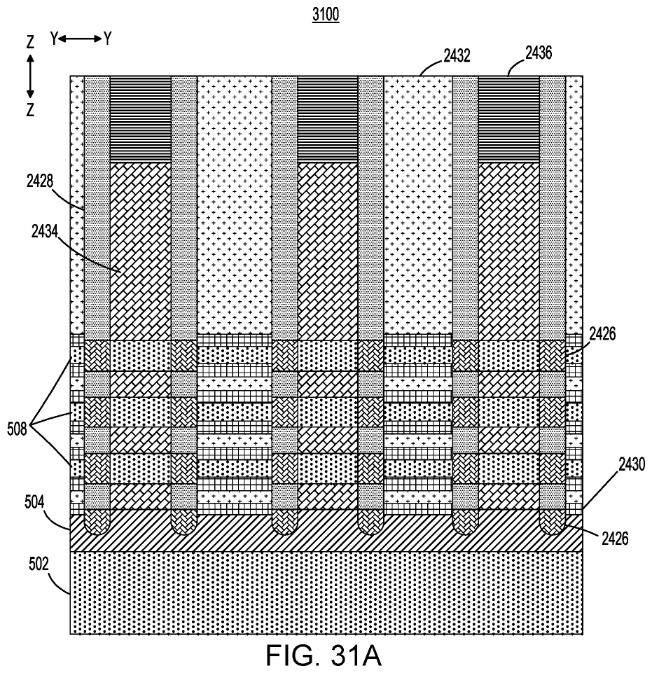

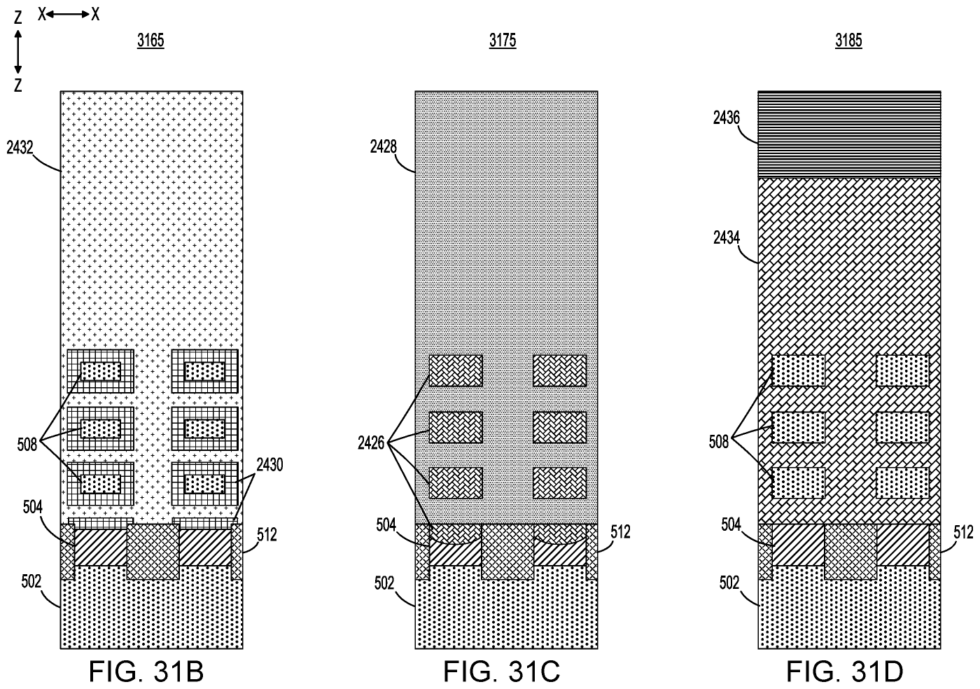

FIGS. 31A-31D show respective cross-sectional views 3100, 3165, 3175 and 3185 of the structure of FIGS. 30A-30D following formation of a gate stack 2434 and SAC capping layers 2436. The gate stack 2434 and SAC capping layers 2436 may be formed of similar materials, and with similar sizing and processing as that described above with respect to the gate stack 534 and SAC capping layers 536.

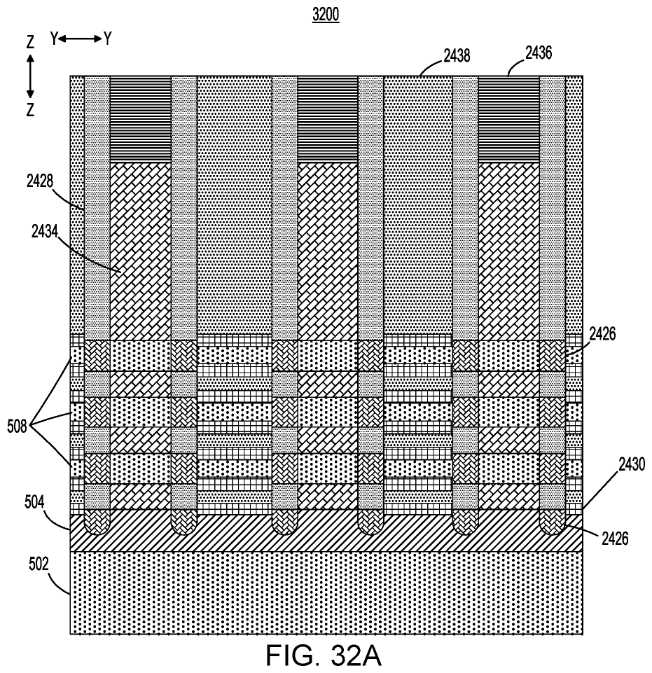

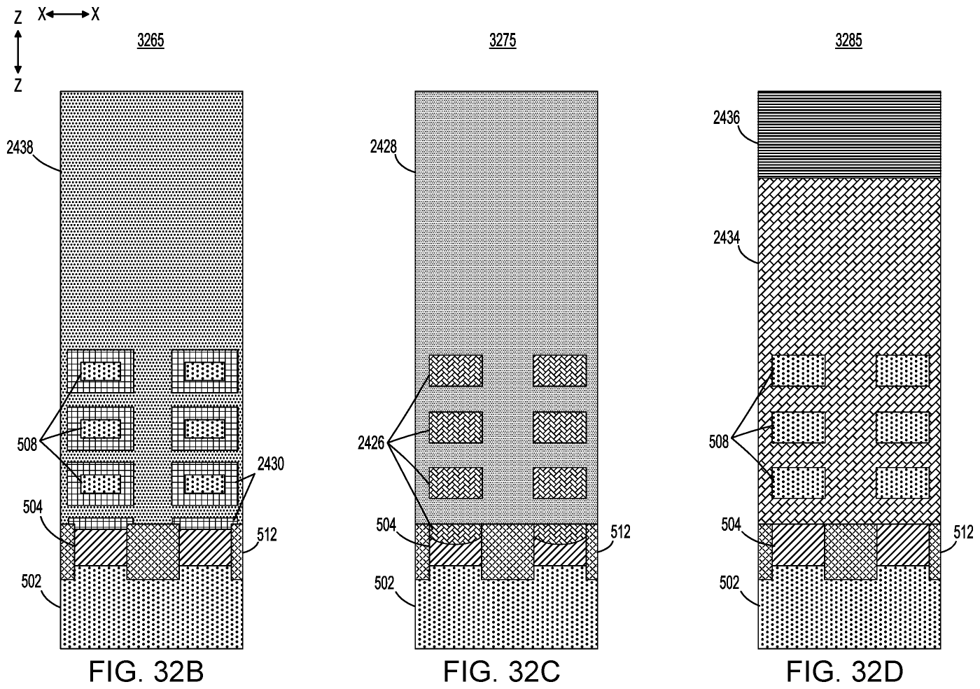

FIGS. 32A-32D show respective cross-sectional views 3200, 3265, 3275 and 3285 of the structure of FIGS. 31A-31D following formation of wrap-all-around contacts 2438. The wrap-all-around contacts 2438 may be formed of similar materials, and with similar sizing and processing as that described above with respect to the wrap-all-around contacts 538.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

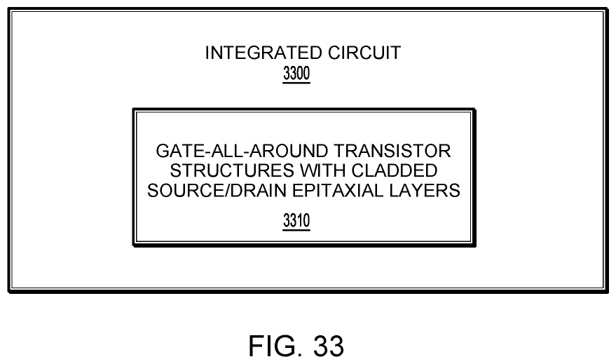

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 33 shows an example integrated circuit 3300 which includes one or more gate-all-around transistor structures 3310 with cladded source/drain epitaxial layers.

In some embodiments, a semiconductor structure includes a gate region, a source/drain region, and a nanosheet semiconductor layer extending continuously across the gate region and the source/drain region. The nanosheet semiconductor layer includes a first portion extending through the gate region and a second portion extending through the source/drain region. The source/drain region includes a cladded epitaxial layer wrapping around the second portion of the nanosheet semiconductor layer.

The semiconductor structure may further include a gate spacer disposed between the gate region and the source/drain region.

The first portion of the nanosheet semiconductor layer may have a first thickness and the second portion of the nanosheet semiconductor layer may have a second thickness different than the first thickness. The second thickness may be less than the first thickness.

The nanosheet semiconductor layer may further include a third portion between the first portion and the second portion, the third portion including a doped region. The transistor may be an n-type transistor, and the doped region may include one or more n-type dopants. The transistor may alternatively be a p-type transistor, and the doped region may include one or more p-type dopants. In some embodiments, the first portion of the nanosheet semiconductor layer has a first thickness, the second portion of the nanosheet semiconductor layer has a second thickness, and the third portion of the semiconductor layer has a third thickness, the first thickness and the third thickness each being greater than the second thickness. In other embodiments, the first portion of the nanosheet semiconductor layer has a first thickness, the second portion of the nanosheet semiconductor layer has a second thickness, and the third portion of the semiconductor layer has a third thickness, the first thickness being greater than the second thickness and the third thickness being greater than the first thickness.

The semiconductor structure may further include a wrap-all-around contact surrounding the cladded epitaxial layer wrapping around the second portion of the nanosheet semiconductor layer.

The gate region may wrap all around the first portion of the nanosheet semiconductor layer.

In some embodiments, a gate-all-around transistor includes a gate region, a source/drain region, and a plurality of nanosheet semiconductor layers extending continuously across the gate region and the source/drain region. Each of the plurality of nanosheet semiconductor layers includes a first portion extending through the gate region and a second portion extending through the source/drain region. The source/drain region includes cladded epitaxial layers wrapping around the second portion of each of the plurality of nanosheet semiconductor layers.

The first portion of each of the plurality of nanosheet semiconductor layers may have a first thickness and the second portion of each of the plurality of nanosheet semiconductor layers may have a second thickness different than the first thickness. The second thickness may be less than the first thickness.

The gate-all-around transistor may further include a wrap-all-around contact surrounding the cladded epitaxial layers wrapping around the second portion of each of the plurality of nanosheet semiconductor layers.

The gate region may wrap all around the first portion of each of the plurality of nanosheet semiconductor layers.

In some embodiments, an integrated circuit includes a gate-all-around transistor structure including a gate region, a source/drain region, and a plurality of nanosheet semiconductor layers extending continuously across the gate region and the source/drain region, each of the plurality of nanosheet semiconductor layers including a first portion extending through the gate region and a second portion extending through the source/drain region. The source/drain region includes cladded epitaxial layers wrapping around the second portion of each of the plurality of nanosheet semiconductor layers.

The first portion of each of the plurality of nanosheet semiconductor layers may have a first thickness and the second portion of each of the plurality of nanosheet semiconductor layers may have a second thickness different than the first thickness.

The integrated circuit may further include a wrap-all-around contact surrounding the cladded epitaxial layers wrapping around the second portion of each of the plurality of nanosheet semiconductor layers.

The gate region may wrap all around the first portion of each of the plurality of nanosheet semiconductor layers.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a gate region;
a source/drain region; and
a nanosheet semiconductor layer extending continuously across the gate region and the source/drain region, the nanosheet semiconductor layer comprising a first portion extending through the gate region and a second portion extending through the source/drain region;
wherein the source/drain region comprises a cladded epitaxial layer wrapping around the second portion of the nanosheet semiconductor layer.

2. The semiconductor structure of claim 1, further comprising a gate spacer disposed between the gate region and the source/drain region.

3. The semiconductor structure of claim 1, wherein the first portion of the nanosheet semiconductor layer has a first thickness and the second portion of the nanosheet semiconductor layer has a second thickness different than the first thickness.

4. The semiconductor structure of claim 3, wherein the second thickness is less than the first thickness.

5. The semiconductor structure of claim 1, wherein the nanosheet semiconductor layer further comprises a third portion between the first portion and the second portion, wherein the third portion comprises a doped region.

6. The semiconductor structure of claim 5, wherein the semiconductor structure comprises an n-type transistor, and the doped region comprises one or more n-type dopants.

7. The semiconductor structure of claim 5, wherein the semiconductor structure comprises a p-type transistor, and the doped region comprises one or more p-type dopants.

8. The semiconductor structure of claim 5, wherein the first portion of the nanosheet semiconductor layer has a first thickness, the second portion of the nanosheet semiconductor layer has a second thickness, and the third portion of the nanosheet semiconductor layer has a third thickness, the first thickness and the third thickness each being greater than the second thickness.

9. The semiconductor structure of claim 5, wherein the first portion of the nanosheet semiconductor layer has a first thickness, the second portion of the nanosheet semiconductor layer has a second thickness, and the third portion of the nanosheet semiconductor layer has a third thickness, the first thickness being greater than the second thickness and the third thickness being greater than the first thickness.

10. The semiconductor structure of claim 1, further comprising a wrap-all-around contact surrounding the cladded epitaxial layer wrapping around the second portion of the nanosheet semiconductor layer.

11. The semiconductor structure of claim 1, wherein the gate region wraps all around the first portion of the nanosheet semiconductor layer.

12. A gate-all-around transistor comprising:
a gate region;
a source/drain region; and
a plurality of nanosheet semiconductor layers extending continuously across the gate region and the source/drain region, each of the plurality of nanosheet semiconductor layers comprising a first portion extending through the gate region and a second portion extending through the source/drain region;
wherein the source/drain region comprises cladded epitaxial layers wrapping around the second portion of each of the plurality of nanosheet semiconductor layers.

13. The gate-all-around transistor of claim 12, wherein the first portion of each of the plurality of nanosheet semiconductor layers has a first thickness and the second portion of each of the plurality of nanosheet semiconductor layers has a second thickness different than the first thickness.

14. The gate-all-around transistor of claim 13, wherein the second thickness is less than the first thickness.

15. The gate-all-around transistor of claim 12, further comprising a wrap-all-around contact surrounding the cladded epitaxial layers wrapping around the second portion of each of the plurality of nanosheet semiconductor layers.

16. The gate-all-around transistor of claim 12, wherein the gate region wraps all around the first portion of each of the plurality of nanosheet semiconductor layers.

17. An integrated circuit comprising:
a gate-all-around transistor structure comprising:
a gate region;
a source/drain region; and
a plurality of nanosheet semiconductor layers extending continuously across the gate region and the source/drain region, each of the plurality of nanosheet semiconductor layers comprising a first portion extending through the gate region and a second portion extending through the source/drain region;
wherein the source/drain region comprises cladded epitaxial layers wrapping around the second portion of each of the plurality of nanosheet semiconductor layers.

18. The integrated circuit of claim 17, wherein the first portion of each of the plurality of nanosheet semiconductor layers has a first thickness and the second portion of each of the plurality of nanosheet semiconductor layers has a second thickness different than the first thickness.

19. The integrated circuit of claim 17, further comprising a wrap-all-around contact surrounding the cladded epitaxial layers wrapping around the second portion of each of the plurality of nanosheet semiconductor layers.

20. The integrated circuit of claim 17, wherein the gate region wraps all around the first portion of each of the plurality of nanosheet semiconductor layers.
